(19) United States
(12) Patent Application Publication
(10) Pub. No.: US 2010/0232127 A1
(43) Pub. Date: Sep. 16, 2010

(54) WIRING BOARD COMPOSITE BODY, SEMICONDUCTOR DEVICE, AND METHOD FOR MANUFACTURING THE WIRING BOARD COMPOSITE BODY AND THE SEMICONDUCTOR DEVICE

(75) Inventors: Kentaro Mori, Tokyo (JP); Shintaro Yamamichi, Tokyo (JP); Katsumi Kikuchi, Tokyo (JP); Hideya Murai, Tokyo (JP); Takuo Funaya, Tokyo (JP); Takehiko Maeda, Kawasaki-shi (JP); Hirokazu Honda, Kawasaki-shi (JP); Kenta Ogawa, Kawasaki-shi (JP); Jun Tsukano, Kawasaki-shi (JP)

Correspondence Address: YOUNG & THOMPSON, 209 Madison Street, Suite 500, Alexandria, VA, 22314, US

(73) Assignee: NEC ELECTRONICS CORPORATION, Kawasaki-shi (JP)

(21) Appl. No.: 12/439,933

(22) PCT Filed: Sep. 4, 2007
(86) PCT No.: PCT/JP2007/067237

§ 371 Date: Apr. 2, 2009

(30) Foreign Application Priority Data
Sep. 4, 2006 (JP) 2006-238997

(51) Int. Cl. H05K 1/18; H05K 1/02; H05K 3/00

(52) U.S. Cl. 361/783; 174/255; 29/829

(57) ABSTRACT

A wiring board composite body includes a supporting substrate, and wiring boards formed on each of the upper and the lower surfaces of the supporting substrate. The supporting substrate includes a supporting body, and a metal body arranged on each of the upper and the lower surfaces of the supporting body. The wiring board comprises at least an insulation layer insulating upper and lower wirings, and a via connecting the upper and the lower wirings. The wiring board mounted on the metal body constitutes a wiring board with the metal body. Thus, the supporting body supporting the metal body is effectively used in a process of forming the wiring board on the metal body, and the wiring board composite body, which has advantageous structural and production characteristics, is provided. A semiconductor device and a method for manufacturing such wiring board composite body and the semiconductor device are also provided.

### TECHNICAL FIELD

The present invention relates to a wiring board composite body provided by forming multi-layer wirings on a supporting substrate composed of a supporting body and a metal body, a semiconductor device having a semiconductor element mounted on the wiring board composite body, and a method for manufacturing the wiring board composite body and the semiconductor device, and a method for manufacturing a wiring board.

### BACKGROUND ART

Recently, there are increasing needs for SiP (System in Package) as a technology for downsizing and enhancing functionality of electronic instruments, which constructs a system with a single package by combining a plurality of existing chips. Currently, a buildup substrate is mainly used as the SiP substrate. As described in Patent Literature 1, a buildup substrate is formed by laminating an insulating layer and a wiring layer alternately on both sides of a core substrate. With rising expectations for the SiP technology, there is a demand for ever-more improvement in high-speed capability and ever-denser micro wiring of the buildup substrates.

To meet such requirements, it is required to form, on the conventional buildup substrate, a wiring board which does not have a core substrate (referred to as coreless substrate, hereafter). With a purpose of suppressing warping of the wiring board, a coreless substrate is formed as a wiring board with less warping, as described in Patent Literature 2, by forming a wiring board on both sides of a composite metal body composed of two sheets of metal bodies adhered to each other and subsequently separating the composite metal body.

Patent Literature 1: Unexamined Japanese Patent Application KOKAI Publication No. H11-17058

Patent Literature 2: Unexamined Japanese Patent Application KOKAI Publication No. 2005-5742

### DISCLOSURE OF INVENTION

### Problems to be Solved by the Invention

However, the above-mentioned conventional technologies have the following problems.

With the buildup substrate described in Patent Literature 1, there are problems such that through holes on the core substrate are obstructive for the speeding-up, and warping and swells occur on the core substrate during formation of the buildup layer, making it difficult to provide finer and higher-density wirings.

In addition, with regard to the coreless substrate described in Patent Literature 2, since a metal film and an adhesive layer are used as the interface of the composite metal body composed of two sheets of metal bodies adhered to each other, it is difficult to separate them since they are highly adhesive, whereby the wiring board can possibly be distorted when separating them. In addition, if the two sheets of metal bodies are thin, it is difficult to completely suppress warping of the wiring board. Furthermore, since the metal body is flat, the number of wiring boards formed is at most two, and production quantity of wiring boards is small.

It is thus an object of the present invention, conceived in view of the above problems, to provide a wiring board composite body, a semiconductor device, and a method for manufacturing the wiring board composite body and the semiconductor device, which have less warping and swells in the manufacturing process of the wiring board composite body as well as in the finished structure, and can increase the wiring board production quantity, by effectively using a supporting body which supports a metal body in the process of forming the wiring board on the metal body.

### Means for Solving the Problems

A wiring board composite body according to the present invention is characterized in that it comprises a supporting body, a metal body arranged on the supporting body, and a plurality of wiring boards formed on the metal body supported by the supporting body, wherein the wiring boards comprise an insulation layer, upper and lower wirings insulated by the insulation layer, and a via for connecting the upper and the lower wirings.

In addition, an arrangement is possible wherein the metal body is arranged on each of a plurality of surfaces of the single supporting body, and the wiring board is formed on the metal body.

In addition, an arrangement is possible wherein the metal body is plurally provided on the single supporting body, and the wiring boards are formed on the metal bodies.

In addition, an arrangement is possible wherein the metal body is arranged on the plurality of supporting bodies in a manner lying between the adjacent supporting bodies, whereby the supporting bodies and the metal body is integrated and the wiring board is formed on the metal body.

In addition, an arrangement is possible wherein the metal body is formed in a bent manner to extend from the front to the back of the single supporting body around its side, whereby the metal body is supported by the supporting body.

In addition, an arrangement is possible wherein the cross section of the metal body is C-shaped, and the supporting body is sandwiched at an open end of the metal body, whereby the metal body is supported by the supporting body.

It is preferred that a low-adhesive interface, which facilitates separation of the adhesion surface, is formed either between the supporting body and the metal body or between the metal body and the wiring board, or both. For example, the low-adhesive interface is provided by forming, between the supporting body and the metal body, a layer composed of a material which is different from the material of the supporting body and the metal body, whereas the low-adhesive interface is provided by forming, between the metal body and the wiring board, a layer composed of a material which is different from the material of the metal body and the wiring board.

An arrangement is possible wherein the supporting body and/or the metal body has a first and a second layers, each composed of their respective component materials, and a low-adhesive interface is formed between the first layer and the second layer by forming, between the first and the second layer, a third layer composed of a material which is different from the component material.

A semiconductor device according to the present invention is characterized in that a semiconductor element is connected to the wiring board composite body.

In addition, an arrangement is possible wherein the semiconductor element is connected to the wiring board composite body by flip-chip connection or wire-bonding connection.

A method for manufacturing a wiring board composite body according to the present invention is characterized in that it comprises a process of forming a supporting substrate composed of a supporting body and a metal body, and a process of forming a plurality of wiring boards on one or more planes on the metal bodies in the supporting substrate comprising an insulating layer, upper and lower wirings insulated by the insulating layer, and a via for connecting the upper and the lower wirings.

In addition, the supporting body and the metal bodies can be integrated by providing the one or more metal bodies on one or more planes of the supporting body in the process of forming the supporting substrate composed of the supporting body and the metal body. In addition, the plurality of metal bodies can be provided on the same plane of the supporting body in the process of forming the supporting substrate composed of the supporting body and the metal bodies. Furthermore, the metal body can be bent to form a plurality of planes on the metal body in the process of forming the supporting substrate composed of the supporting body and the metal body.

A method for manufacturing a wiring board according to the present invention is characterized in that it comprises the steps of: forming a supporting substrate composed of a supporting body and a metal body; forming a plurality of wiring boards on one or more planes on the metal body in the supporting substrate comprising an insulating layer, upper and lower wirings insulated by the insulating layer, and a via for connecting the upper and the lower wirings; and separating the wiring board from a wiring board composite body formed of the supporting substrate and the wiring board.

A method for manufacturing of a wiring board according to the present invention is characterized in that it comprises the steps of: forming a supporting substrate composed of a supporting body and a metal body; forming a plurality of wiring boards on one or more planes on the metal body in the supporting substrate comprising an insulating layer, upper and lower wirings insulated by the insulating layer, and a via for connecting the upper and the lower wirings; and separating the wiring board having the metal body integrated therewith from a wiring board composite body formed of the supporting substrate and the wiring board.

In addition, a process of separating the wiring board and the metal body can be added subsequent to the process of separating the wiring board having the metal body integrated therewith. In this occasion, either the metal body may be completely separated from the wiring board, or a portion of the metal body may be left on the wiring board.

A method for manufacturing a semiconductor device according to the present invention is characterized in that a semiconductor element is mounted on the wiring board composite body manufactured by the method for manufacturing the wiring board composite body.

In addition, the supporting body can be separated from the wiring board composite body after the semiconductor element has been mounted on the wiring board composite body.

In addition, the supporting body and the metal body can be separated from the wiring board composite body after the semiconductor element has been mounted on the wiring board composite body.

A method for manufacturing a semiconductor device according to the present invention is characterized in that a semiconductor element is mounted on a wiring board manufactured by the method for manufacturing the wiring board.

In addition, the semiconductor device and the wiring board can be connected by flip-chip connection or wire-bonding connection in the process of mounting the semiconductor element.

### EFFECT OF THE INVENTION

In the wiring board composite body and the semiconductor device using the wiring board composite body according to the present invention, the wiring board composite body and the semiconductor device using the wiring board composite body are formed using a supporting substrate composed of a supporting body and metal bodies. If the material of the supporting body has a high rigidity, the supporting substrate is in a condition with less warping and swells so that the wiring board composite body formed using the supporting substrate and the semiconductor device using the wiring board composite body will be a stable structure with less warping and swells, whereby connectivity of the semiconductor element such as wire-bonding or flip-chip connection and transportability in the assembly process are improved and productivity is increased. If, on the other hand, the material of the supporting body is flexible, a wiring board composite body and a semiconductor device using the wiring board composite body can be formed at low cost, since roll-to-roll or reel-to-reel production can be employed.

In addition, with the method for manufacturing a wiring board composite body and a wiring board according to the present invention, a plurality of wiring boards can be formed by using, as the supporting body, a polygonal column or the like which has a plurality of surfaces, whereby the wiring board production quantity increases. In addition, roll-to-roll or reel-to-reel production which realizes a very high productivity can be employed by causing the supporting body to function as a joint for mutually joining a plurality of wiring boards with metal bodies. By effectively utilizing the supporting body as thus described, labor and equipment associated with transportation in the manufacturing process can be substantially saved, whereby the manufacturing cost can be reduced.

Furthermore, with the method for manufacturing a semiconductor device according to the present invention, mounting precision and connection reliability can be enhanced, since semiconductor elements may be mounted on a stable wiring board composite body and a wiring board with less warping and swells.

### BRIEF DESCRIPTION OF DRAWINGS

FIG. 1 is a partial cross-sectional view illustrating the structure of a wiring board composite body according to a first embodiment of the present invention.

FIG. 2 is a cross-sectional view illustrating an example of the structure of a wiring

board provided with the metal body in the present embodiment.

FIG. 3 is a partial cross-sectional view illustrating the structure of a wiring board composite body according to a second embodiment of the present invention.

FIG. 4 is a partial cross-sectional view illustrating the structure of a wiring board composite body according to a third embodiment of the present invention.

FIG. 5 is a partial cross-sectional view illustrating the structure of a wiring board composite body according to a fourth embodiment of the present invention.

FIG. 6 is a partial cross-sectional view illustrating the structure of the wiring board composite body according to an exemplary variation of the fourth embodiment of the present invention.

FIG. 7 is a partial cross-sectional view illustrating the structure of a wiring board composite body according to a fifth embodiment of the present invention.

FIG. 8 is a partial cross-sectional view illustrating the structure of a wiring board composite body according to an exemplary variation of the fifth embodiment of the present invention.

FIG. 9 is a partial cross-sectional view illustrating the structure of a semiconductor device according to a sixth embodiment of the present invention.

FIG. 10 is a partial cross-sectional view illustrating the structure of a semiconductor device according to a seventh embodiment of the present invention.

FIG. 11 is a partial cross-sectional view illustrating the structure of a semiconductor device according to an eighth embodiment of the present invention.

FIG. 12 is a partial cross-sectional view illustrating, in the order of processes, the method for manufacturing a wiring board composite body and a wiring board according to a ninth embodiment of the present invention.

FIG. 13 is a cross-sectional view illustrating, in the order of processes, the method for manufacturing a wiring board in the present invention.

FIG. 14 is a partial cross-sectional view illustrating, in the order of processes, the method for manufacturing a wiring board composite body and a wiring board according to a first exemplary variation of the ninth embodiment.

FIG. 15 is a partial cross-sectional view illustrating, in the order of processes, the method for manufacturing a wiring board composite body and a wiring board according to a second exemplary variation of the ninth embodiment.

FIG. 16 is a partial cross-sectional view illustrating, in the order of processes, the method for manufacturing a wiring board composite body and a wiring board according to a tenth embodiment of the present invention.

FIG. 17 is a partial cross-sectional view illustrating, in the order of processes, the method for manufacturing a wiring board composite body and a wiring board according to an eleventh embodiment of the present invention.

FIG. 18 is a partial cross-sectional view illustrating, in the order of processes, the method for manufacturing a wiring board composite body and a wiring board according to a twelfth embodiment of the present invention.

FIG. 19 is a partial cross-sectional view illustrating, in the order of processes, the method for manufacturing a wiring board composite body and a wiring board according to a thirteenth embodiment of the present invention.

FIG. 20 is a partial cross-sectional view illustrating, in the order of processes, the method for manufacturing a semiconductor device according to a fourteenth embodiment of the present invention.

FIG. 21 is a partial cross-sectional view illustrating, in the order of processes, the method for manufacturing a semiconductor device according to a fifteenth embodiment of the present invention.

### DESCRIPTION OF REFERENCE NUMERALS

11; wiring board composite body
12; supporting body
13; metal body
14; wiring board
15; supporting substrate
16; wiring board with metal body
17; insulating layer
18; lower wiring
19; via
20; upper wiring
21; wiring layer
22; solder resist
23; solder ball
24; semiconductor element
25; underfill resin
26; bonding wire
27; semiconductor device
28; mold resin
125; adhesive

### BEST MODE FOR CARRYING OUT THE INVENTION

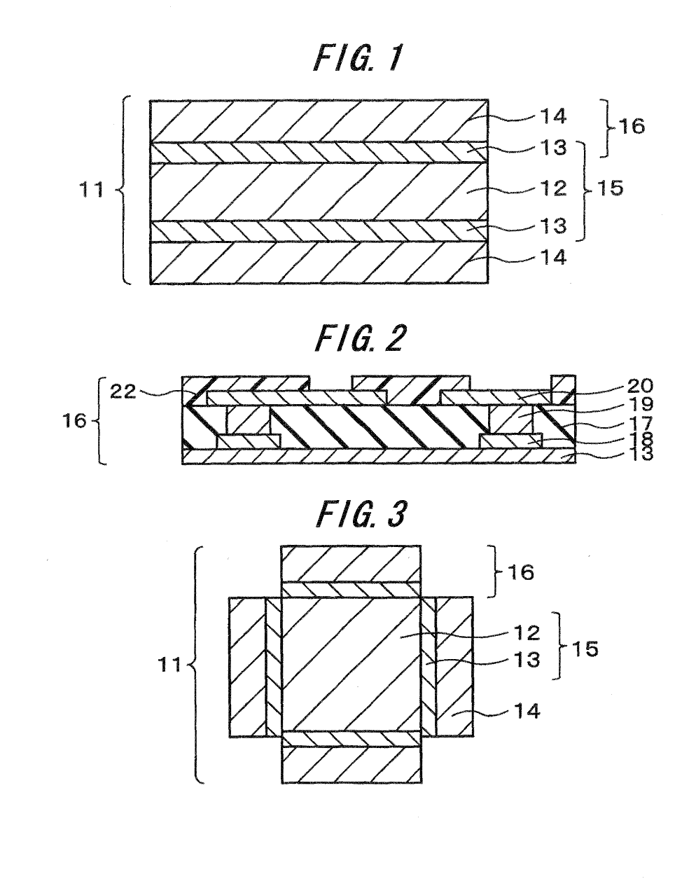

Embodiments of the present invention will be described in detail below, referring to the drawings. FIG. 1 is a partial cross-sectional view illustrating the structure of a wiring board composite body according to a first embodiment of the present invention. As shown in FIG. 1, a wiring board composite body 11 according to the present embodiment is composed of a supporting substrate 15 and wiring boards 14 formed on each of the upper and the lower surfaces of the supporting substrate 15. The supporting substrate 15 is composed of a supporting body 12 having a planar-shape or the like, and metal bodies 13 having a planar-shape or the like arranged on each of the upper and the lower surfaces of the supporting body 12. In addition, the wiring board 14 comprises at least an insulating layer, upper and lower wirings insulated by the insulating layer, and a via for connecting the upper and the lower wirings. The wiring board 14, which is integrated with the metal body 13, constitutes a wiring board 16 provided with the metal body.

The supporting body 12 may be composed of organic compounds such as epoxy resin, epoxy acrylate resin, urethane acrylate resin, polyester resin, phenol resin, polyimide resin, BCB (benzocyclobutene), PBO (polybenzoxazole), or polynorbornene resin; inorganic compounds such as ceramic, metal oxide, or glass; or metals such as copper, nickel, aluminum, gold, silver, palladium, platinum, iron, stainless steel, zinc, magnesium, titanium, 42 alloy, chromium, vanadium, rhodium, molybdenum or cobalt; and may also be composed of a plurality of these materials. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of any one of copper, nickel, aluminum, gold, silver, palladium, platinum, iron, stainless steel, zinc, magnesium, titanium, 42 alloy, chromium, vanadium, rhodium, molybdenum and cobalt, for example, or a combination of these metal materials. Particularly, copper is suitable in terms of cost and workability. In the present embodiment, copper is used as the metal body 13. In addition, the metal body 13 is provided on at least a portion of one or more planes formed on the surface of the supporting body 12. Furthermore, the metal body 13 may have the same shape or size, in planar view, as the plane formed on the supporting body 12, or may have a different shape or size.

FIG. 2 is a cross-sectional view illustrating an example of structure of a wiring board provided with the metal body in the present embodiment. As shown in FIG. 2, a wiring board 16 provided with the metal body is composed of a planar metal body 13, a lower wiring 18 formed on the metal body 13, an insulating layer 17 laminated on the metal body 13 including the lower wiring 18, an upper wiring 20 formed on the insulating layer 17, a via 19 vertically passing through the insulating layer 17 to electrically connect the lower wiring 18 and the upper wiring 20, and a solder resist 22 formed on the insulating layer 17 including a portion of the upper wiring 20. Although FIG. 2 illustrates an exemplary arrangement consisting of a single-level insulating layer 17, and a lower wiring 18 and an upper wiring 20 formed on the top and the bottom of the insulating layer 17, such an arrangement is not limiting and thus a multi-layer wiring structure may be employed, with a plurality of layers of such a structure laminated thereon.

The insulating layer 17 is composed of a photosensitive or a non-photosensitive organic material, for example, wherein the organic material may be epoxy resin, epoxy acrylate resin, urethane acrylate resin, polyester resin, phenol resin, polyimide resin, BCB (benzocyclobutene), PBO (polybenzoxazole) or polynorbornene resin, for example, and further, materials such as woven or unwoven fabric formed by glass cloth or aramid fiber with epoxy resin, epoxy acrylate resin, urethane acrylate resin, polyester resin, phenol resin, polyimide resin, BCB (benzocyclobutene), PBO (polybenzoxazole) or polynorbornene resin impregnated therein may be employed. In the present embodiment, epoxy resin with aramid fiber impregnated therein is used.

The lower wiring 18, the via 19, and the upper wiring 20 may be composed of at least one type of metal selected from a group including for example, copper, silver, gold, nickel, aluminum and palladium, or an alloy having these metals as major components. Particularly, it is preferred, in terms of electrical resistance and cost, to be composed of copper. In the present embodiment, copper is used.

The lower wiring 18 and the upper wiring 20 are formed by a method such as subtractive, semi-additive, or full-additive methods, for example. The subtractive method is a method which forms a resist of desired pattern on copper foil provided on the substrate and, after having etched unnecessary copper foil, strips the resist to obtain the desired pattern. The semi-additive method is a method which forms a resist having an opening with a desired pattern after having formed a power supplying layer by electroless plating, spattering or CVD (chemical vapor deposition) method or the like, deposits metal within the resist opening by electroplating and, after having removed the resist, etches the power supplying layer to obtain the desired wiring pattern. The full-additive method is a method which forms a pattern using the resist after having absorbed the electroless plating catalyst on the substrate, activates the catalyst with the resist left as an insulator film, deposits metal at the opening of the insulator by electroless plating to obtain the desired wiring pattern. In the present embodiment, the semi-additive method is employed.

The lower wiring 18 and the upper wiring 20 are electrically connected by the via 19 provided in the insulating layer 17. When an organic material is employed as the insulating layer 17, an opening of the insulating layer 17 on which the via 19 is provided is formed by photolithography, and at least one type of metal selected from a group including for example, copper, silver, gold, nickel, aluminum and palladium, or an alloy having these metals as major components is filled in the opening. The filling method to be used are electroplating, electroless plating, printing, molten metal suction, or the like. If a non-photosensitive organic material or a photosensitive organic material with a low pattern resolution is used, the opening of the insulating layer 17 on which the via 19 is provided is formed by laser processing, dry etching, or plasma method, and filled with at least one type of metal selected from a group including for example, copper, silver, gold, nickel, aluminum and palladium, or an alloy having these metals as major components. The filling methods to be used are electroplating, electroless plating, molten metal suction, or the like. In addition, according to a method in which the insulating layer 17 is formed after having formed a post for electric conduction at the position of the via 19 beforehand, and the via 19 is formed by grinding the surface of the insulating layer 17 by polishing to expose the electric conduction post, it is not necessary to provide an opening on the insulating layer 17. In the present embodiment, laser processing is employed and copper is used as the material for all of the lower wiring 18, the upper wiring 20, and the via 19.

A solder resist 22 is formed on the insulating layer 17 so as to expose a portion of the upper wiring 20 and cover the remaining portion. In the present embodiment, photoresist ink is used as the material of the solder resist 22. Exposed part of the upper wiring 20 becomes a pad electrode.

In the wiring board composite body 11, it is preferred to integrate the supporting body 12 and the metal body 13 by forming a low-adhesive interface between the supporting body 12 and the metal body 13. Since it is easy to separate the supporting body 12 from the wiring board composite body 11, forming a low-adhesive interface is preferable for separating the wiring board 16 provided with the metal body. If the supporting body 12 is composed of the above-mentioned metal material, for example, the interface between the oxide film and the metal body 13 becomes a low-adhesive interface by forming an oxide film on the surface of the supporting body 12 at the contact surface between the supporting body 12 and the metal body 13 and integrating the supporting body 12 and the metal body 13 through the oxide film. Alternatively, an oxide film may be formed on the surface of the metal body 13 to render the interface between the oxide film and the supporting body 12 to be low-adhesive. Note that the above method of forming a low-adhesive interface through an oxide film is an example without limiting the invention, and any method will suffice provided that separation between the supporting body 12 and the metal body 13 is easy. Similarly, the metal body 13 and the wiring board 14 may be integrated by forming a low-adhesive interface between the metal body 13 and the wiring board 14, whereby the wiring board 14 can be easily separated from the metal body 13. Furthermore, the supporting body 12 itself may have a structure which can be easily separated into a plurality of parts. For example, in FIG. 1, if the supporting body 12 has a structure which can be easily separated into two parts along a plane parallel to the surface of the wiring board 14, the wiring board composite body 11 can be easily separated into two wiring boards 16 associated with metal bodies, each having a portion of the supporting body 12 provided thereon. For example, two metal plates adhered to each other through an oxide film may be used as such a supporting body 12. As thus described, in the supporting body 12 having a two-layer structure composed of two metal plates, the portion between the oxide film and the metal plate becomes a low-adhesive interface. Similarly, the metal body 13 itself may have a structure which can be easily separated into a plurality of parts, for example, a two-layer structure composed of two metal plates having an oxide film therebetween. In this occasion, the metal body 13 can be easily separated into two parts at the low adhesive interface between the oxide film and the metal plate.

Next, the operation and effect of the present embodiment will be described. In the present embodiment, the wiring board composite body 11 is formed using the supporting substrate 15 composed of the supporting body 12 and the metal body 13. Furthermore, the supporting body 12 is composed of highly rigid material. Therefore, the wiring board composite body 11 formed from the supporting substrate 15 will be a stable structure with less warping and swells. In addition, occurrence of warping and swells is also suppressed in the wiring board 14 formed on the wiring board composite body 11. Furthermore, by rendering the separation surface to be a low-adhesive interface when separating the wiring board 14 or the wiring board 16 provided with the metal body from the wiring board composite body 11, separation at the interface can be performed easily. Therefore, occurrence of distortion such as warping and swells after separation can be suppressed on the wiring board 14 or the wiring board 16 provided with the metal body.

Next, a wiring board composite body according to a second embodiment of the present invention will be described. FIG. 3 is a partial cross-sectional view illustrating the structure of a wiring board composite body according to a second embodiment of the present invention.

As shown in FIG. 3, the wiring board composite body 11 according to the present embodiment comprises metal bodies 13 having a planar-shape or the like provided on each of the four planes of a quadrangular prism-shaped supporting body 12, and the wiring board 14 of the first embodiment, that is, the wiring board 14 comprising at least an insulating layer, upper and lower wirings insulated by the insulating layer, and a via for connecting the upper and the lower wirings is formed on each of the metal bodies 13. The wiring board 14, which is integrated with the metal body 13, constitutes a wiring board 16 provided with the metal body, and four of such wiring boards 16 associated with metal bodies are formed in the present embodiment. Although a quadrangular prism is used as an example of the supporting body 12 in FIG. 3, a polygonal column, a polyhedron, or a cylindrical column having a plurality of surfaces may be employed other than a quadrangular prism.

The supporting body 12 may be composed of a material similar to the first embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13. In addition, the metal body 13 is provided on at least a portion of one or more planes formed on the surface of the supporting body 12. Furthermore, the metal body 13 may have the same shape or size, in planar view, as the plane formed on the supporting body 12, or may have a different shape or size. A plane is formed on the metal body 13, and the wiring board 14 is formed on the plane.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Next, the operation and effect of the present embodiment will be described. In the present embodiment, the wiring board composite body 11 is formed using the supporting substrate 15 composed of the supporting body 12 and the metal body 13. Furthermore, the supporting body 12 is composed of highly rigid material. Therefore, the wiring board composite body 11 formed from the supporting substrate 15 will be a stable structure with less warping and swells. In addition, production quantity of the wiring board 14 can be increased, since the wiring board 14 having a plurality (four) of metal bodies 13 on a plurality (four) of surfaces of the supporting body 12 can be formed. Furthermore, by rendering the separation surface to be a low-adhesive interface when separating the wiring board 14 or the wiring board 16 provided with the metal body from the wiring board composite body 11, separation at the interface can be performed easily. Therefore, occurrence of distortion such as warping and swells after separation can be suppressed on the wiring board 14 or the wiring board 16 provided with the metal body.

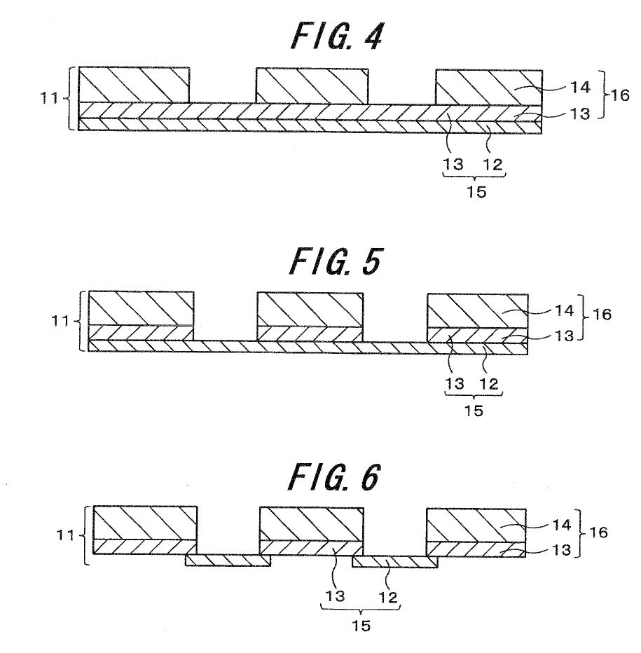

Next, a wiring board composite body according to a third embodiment of the present invention will be described. FIG. 4 is a partial cross-sectional view illustrating the structure of a wiring board composite body according to a third embodiment of the present invention.

As shown in FIG. 4, the wiring board composite body 11 according to the present embodiment comprises a supporting substrate 15 composed of a supporting body 12 having a planar-shape or the like and a metal body 13 having a planar-shape or the like arranged on one side of the supporting body 12. A plurality (three, in the illustrated example) of wiring boards 14 are formed on the metal body 13, and the wiring board 14 comprises at least an insulating layer, upper and lower wirings insulated by the insulating layer, and a via for connecting the upper and the lower wirings. The wiring board 14 has the same structure as the wiring board in the first embodiment shown in FIG. 2. The wiring board 14, which are integrated with the metal body 13, constitutes a wiring board 16 provided with the metal body. In FIG. 4, although a plurality of wiring boards 14 are formed on only one side of the supporting substrate 15 by way of the metal body 13, structure in which a plurality of wiring boards 14 are formed by way of the metal body 13 on both sides of the supporting substrate 15 may also be used.

The supporting body 12 may be composed of a material similar to the first embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13. In addition, the metal body 13 is provided on at least a portion of one or more planes formed on the surface of the supporting body 12. Furthermore, the metal body 13 may have the same shape or size, in planar view, as the plane formed on the supporting body 12, or may have a different shape or size.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Next, the operation and effect of the present embodiment will be described. In the present embodiment, the wiring board composite body 11 is formed using the supporting substrate 15 composed of the supporting body 12 and the metal body 13. Furthermore, the supporting body 12 is composed of highly rigid material. Therefore, the wiring board composite body 11 formed from the supporting substrate 15 will be a stable structure with less warping and swells. If, on the other hand, the supporting body 12 is composed of a flexible material in the arrangement of the present embodiment, the wiring board composite body 11 can be formed at low cost, since roll-to-roll or reel-to-reel production can be employed. Furthermore, production quantity of the wiring board 14 can be increased, since a plurality of wiring boards 14 can be formed on one surface of the supporting body 12 by way of the metal bodies 13. Moreover, by rendering the separation surface to be a low-adhesive interface when separating the wiring board 14 or the wiring board 16 provided with the metal body from the wiring board composite body 11, separation at the interface can be performed easily. Therefore, occurrence of distortion such as warping and swells after separation can be suppressed on the wiring board 14 or the wiring board 16 provided with the metal body.

Next, a wiring board composite body according to a fourth embodiment of the present invention will be described. FIG. 5 is a partial cross-sectional view illustrating the structure of the wiring board composite body according to a fourth embodiment of the present invention.

As shown in FIG. 5, the wiring board composite body 11 according to the present embodiment comprises a supporting substrate 15 composed of a supporting body 12 having a planar-shape or the like, and a plurality (three, in the illustrated example) of metal bodies 13 having a planar-shape or the like arranged on one side of the supporting body 12. Also, wiring boards 14 are formed on the metal bodies 13, and the wiring board 14 comprises at least an insulating layer, upper and lower wirings insulated by the insulating layer, and a via for connecting the upper and the lower wirings. The wiring board 14 has the same structure as the wiring board in the first embodiment shown in FIG. 2. In addition, the wiring board 14, which are integrated with the metal body 13 constitutes a wiring board 16 provided with the metal body. Although a plurality of metal boards 13 are formed on only one side of the supporting substrate 15 and the wiring boards 14 are formed on respective metal bodies 13, in FIG. 5, a structure in which a plurality of metal boards 13 are formed on both sides of the supporting substrate 15 and the wiring boards 14 are formed on respective metal boards 13 may also be used.

The supporting body 12 may be composed of a material similar to the first embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Next, the operation and effect of the present embodiment will be described. In the present embodiment, the wiring board composite body 11 is formed using the supporting substrate 15 composed of the supporting body 12 and the metal body 13. Therefore, the wiring board composite body 11 formed from the supporting substrate 15 will be a stable structure with less warping and swells, if the material of the supporting body 12 is highly rigid. If, on the other hand, the supporting body 12 is composed of a flexible material in the arrangement of the present embodiment, the wiring board composite body 11 can be formed at low cost, since roll-to-roll or reel-to-reel production can be employed. Furthermore, production quantity of the wiring board 14 can be increased, since a plurality of wiring boards 14 can be formed on one surface of the supporting body 12 by way of the metal bodies 13. Moreover, by rendering the separation surface to be a low-adhesive interface when separating the wiring board 14 or the wiring board 16 provided with the metal body from the wiring board composite body 11, separation at the interface can be performed easily. Therefore, occurrence of distortion such as warping and swells after separation can be suppressed on the wiring board 14 or the wiring board 16 provided with the metal body.

Next, a wiring board composite body according to an exemplary variation of the fourth embodiment will be described. FIG. 6 is a partial cross-sectional view illustrating the structure of a wiring board composite body according to an exemplary variation of the fourth embodiment. As shown in FIG. 6, the wiring board composite body 11 according to the exemplary variation has a supporting substrate 15 composed of a plurality of supporting bodies 12 and a plurality of metal bodies 13. The supporting substrate 15 is composed of a plurality of supporting bodies 12 and a plurality of metal bodies 13 integrated by connecting the plurality of metal bodies 13 with each other by way of respective supporting bodies 12 arranged between the metal bodies. Specifically, a plurality (three in the illustrated example) of metal bodies 13 having a planar-shape or the like are arranged mutually spaced apart in a one-dimensional array, a supporting body 12 having a planar-shape or the like is arranged at the lower part between the adjacent metal bodies 13, and the plurality of metal bodies 13 are connected by way of the supporting body 12 therebetween. Particularly, the edge of the top surface of the supporting body 12 is joined with the edge of bottom surface of the metal body 13. In this manner, the supporting substrate 15 is composed of a plurality of supporting bodies 12 and a plurality of metal bodies 13 integrated by joining the supporting body 12 with at least a portion of the metal bodies 13, whereby a wiring board 14 is formed on each of the metal bodies 13. The wiring board 14 comprises at least an insulating layer, upper and lower wirings insulated by the insulating layer, and a via for connecting the upper and the lower wirings. The wiring board 14 has the same structure as the wiring board in the first embodiment shown in FIG. 2. In addition, the wiring board 14, which are integrated with the metal body 13, constitutes a wiring board 16 provided with the metal body. Although the wiring board 16 provided with the metal body is formed on only one side of the supporting substrate 12 in FIG. 6, the wiring board 16 provided with the metal body may be formed on both sides of the supporting substrate 12.

The supporting body 12 may be composed of a material similar to the first embodiment. In addition, the supporting body 12 may be composed of highly rigid material, which can be used repeatedly, or may be composed of highly flexible material, which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Next, the operation and effect of the present embodiment will be described. In the present exemplary variation, the wiring board composite body 11 is formed using the supporting substrate 15 composed of the supporting body 12 and the metal body 13. Therefore, the wiring board composite body 11 formed from the supporting substrate 15 will be a stable structure with less warping and swells, if the material of the supporting body 12 is highly rigid. If, on the other hand, the supporting body 12 is composed of a flexible material in the arrangement of the present exemplary variation, the wiring board composite body 11 can be formed at low cost, since roll-to-roll or reel-to-reel production can be employed. Furthermore, production quantity of the wiring board 14 can be increased, since a plurality of wiring boards 14 can be formed on the wiring board 16 provided with the metal body. Moreover, the amount of usage of the supporting body 12 can be reduced compared with the fourth embodiment shown in FIG. 5, for example, since the supporting body 12 and the metal body 13 are integrated by contacting a portion thereof, which leads to cost reduction. Furthermore, by rendering the separation surface to be a low-adhesive interface when separating the wiring board 14 or the wiring board 16 provided with the metal body from the wiring board composite body 11, separation at the interface can be performed easily. Therefore, occurrence of distortion such as warping and swells after separation can be suppressed on the wiring board 14 or the wiring board 16 provided with the metal body.

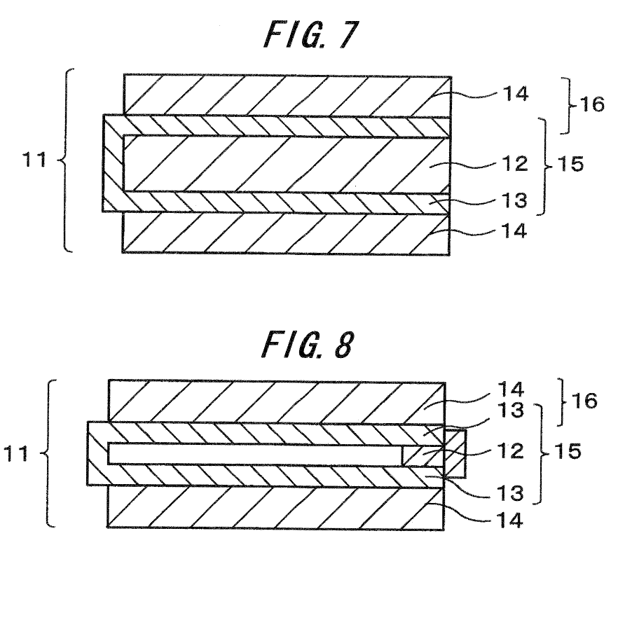

Next, a wiring board composite body according to a fifth embodiment of the present invention will be described. FIG. 7 is a partial cross-sectional view illustrating the structure of the wiring board composite body according to a fifth embodiment of the present invention.

As shown in FIG. 7, the wiring board composite body 11 according to the present embodiment comprises a supporting substrate 15 composed of a supporting body 12 having a planar-shape or the like, and a metal body 13 bent at the edge of the supporting body 12 so as to cover the top and the bottom surfaces and one side of the supporting body 12. That is, the metal body 13 is bent so as to overlap with the front and back sides of the supporting body 12, with the cross section of the metal body 13 being C-shaped. Wiring boards 14 are formed on each of the top and the bottom surfaces of the supporting substrate 15, and the wiring board 14 comprises at least an insulating layer, upper and lower wirings insulated by the insulating layer, and a via for connecting the upper and the lower wirings. The wiring board 14 has the same structure as the wiring board in the first embodiment shown in FIG. 2. In addition, the wiring board 14, which are integrated with the metal body 13, constitutes a wiring board 16 provided with the metal body. Although the bent metal body 13 is arranged along the circumference of the supporting body 12 in FIG. 7, there may be provided a space partially between the supporting body 12 and the metal body 13.

The supporting body 12 may be composed of a material similar to the first embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Additionally, although one wiring board 14 is formed on each of the two planes formed on the bent metal body 13 in FIG. 7, a plurality of wiring boards may be formed.

Next, the operation and effect of the present embodiment will be described. In the present embodiment, the wiring board composite body 11 is formed using the supporting substrate 15 composed of the supporting body 12 and the metal body 13. Therefore, the wiring board composite body 11 formed from the supporting substrate 15 will be a stable structure with less warping and swells, if the material of the supporting body 12 is highly rigid. In addition, since a bent metal body 13 is used, it is not necessary to prepare a plurality of metal bodies 13, whereby material can be reduced and the wiring board composite body 11 can be formed at low cost. Here, other operations and effects are similar to that of the first embodiment.

Next, a wiring board composite body according to an exemplary variation of the fifth embodiment of the present invention will be described. FIG. 8 is a partial cross-sectional view illustrating the structure of a wiring board composite body according to an exemplary variation of the filth embodiment of the present invention.

As shown in FIG. 8, the wiring board composite body 11 according to the exemplary variation has a supporting substrate 15 composed of a metal body 13 formed by bending a planar metal member so that its cross section becomes C-shaped, and a supporting body 12, which are integrated with the metal body 13 in a manner sandwiched at the open end of the metal body 13. Then, a wiring board 14 is provided on each of the two planes formed on the bent metal body 13. Although one wiring board 14 is formed on each plane in the exemplary variation, a plurality of wiring boards may be formed. The wiring board 14 comprises at least an insulating layer, upper and lower wirings insulated by the insulating layer, and a via for connecting the upper and the lower wirings. The wiring board 14 has the same structure as the wiring board in the first embodiment shown in FIG. 2. In addition, although it is preferred that the supporting body 12 is arranged at an open end of the metal body 13, the supporting body 12 can also be arranged and fixed between metal bodies 13 located above and below thereof, at a position separated from the bent portion of the metal body 13 toward the open end by a predefined distance. The wiring board 14, which is integrated with the metal body 13, constitutes a wiring board 16 provided with the metal body. Although the number of supporting bodies 12 is singular in FIG. 8, a plurality of supporting bodies may also be used.

The supporting body 12 may be composed of a material similar to the first embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

The metal body 13 may be composed of a metal material similar to that in the first embodiment. Particularly, copper is suitable in terms of cost and workability. In the present embodiment, copper is used as the metal body 13.

In the wiring board composite body 11, a low-adhesive interface can be provided, as with the first embodiment, either between the supporting body 12 and the metal body 13 or between the metal body 13 and the wiring board 14, or both. According to such an arrangement, separation into the component can be easily performed in each of the interfaces. In addition, the supporting body 12 itself and/or the metal body 13 itself may have a structure which can be easily separated into a plurality of portions, as with the first embodiment.

Next, the operation and effect of the present embodiment will be described. According to the present embodiment, since only a portion of the bent metal body 13 is fixed by the supporting body 12, it becomes possible to reduce the material of the supporting body 12, whereby the wiring board composite body 11 can be formed at low cost. In addition, since a plurality of wiring boards 14 can be formed using a single planar metal body 13, production quantity of the wiring board 14 can be increased. Here, other operations and effects are similar to that of the first embodiment.

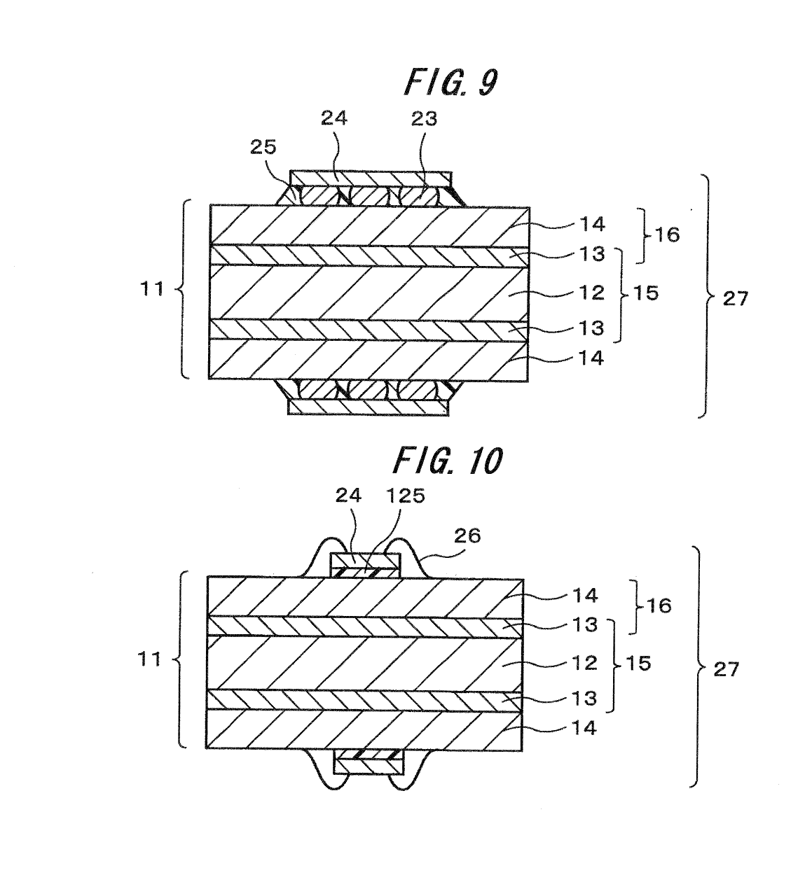

Next, a semiconductor device according to a sixth embodiment of the present invention will be described. FIG. 9 is a partial cross-sectional view illustrating the structure of a semiconductor device according to a sixth embodiment of the present invention.

As shown in FIG. 9, the semiconductor device 27 according to the present embodiment has the wiring board composite body 11 of the first embodiment as shown in FIG. 1. In addition, a semiconductor element 24 is flip-chip connected to the wiring board 14 formed on the wiring board composite body 11 by way of a solder ball 23, and under fill resin 25 is injected between the semiconductor element 24 and the wiring board 14. Although the wiring board composite body of the first embodiment is used as the wiring board composite body 11 in FIG. 9, any wiring board composite body of the second to fifth embodiments can also be used.

The electrode of the semiconductor element 24 is connected to the electrode of the wiring board 14 by way of a solder ball 23, and underfill resin 25 is filled in the space between the semiconductor element 24 and the wiring board composite body 11. The underfill resin 25 reduces the difference of coefficients of thermal expansion between the wiring board composite body 11 and the semiconductor element 24 to prevent destruction of the solder ball 23 due to heat cycle. However, if the solder ball 23 has a strength that assures high reliability, it is not necessary to be filled with the underfill resin 25. The solder ball 23, a ball composed of a solder material, is attached to the wiring board composite body 11 by plating, ball transferring, printing or the like. The solder ball 23 is composed of, for example, eutectic solder of lead/tin alloy or a lead-free solder material. The underfill resin 25 is composed of, for example, an epoxy material with silica filler added thereto. Electroconductive paste or copper bump may be used instead of the solder ball 23 for joining the wiring board composite body 11 and the semiconductor element 24. In the present embodiment, a solder ball 23 is used.

A stiffener and a heat spreader may be mounted on the semiconductor device 27.

Next, the operation and effect of the present embodiment will be described. In the present embodiment, since the semiconductor device 27 is formed using the supporting substrate 15 composed of the supporting body 12 and the metal body 13, the semiconductor device 27 formed by the supporting substrate 15 will be a stable structure with less warping and swells, if the material of the supporting body 12 is highly rigid. Accordingly, mounting precision increases when forming the semiconductor device 27 by mounting the semiconductor element 24 on the wiring board composite body 11. If, on the other hand, the material of the supporting body 12 is flexible, the semiconductor device 27 can be manufactured at low cost, since roll-to-roll or reel-to-reel production can be employed. Furthermore, production quantity of the semiconductor device 27 can be increased, since a wiring board 14 having a plurality of metal bodies 13 can be formed on a plurality of surfaces of the supporting body 12.

Next, a semiconductor device according to a seventh embodiment of the present invention will be described. FIG. 10 is a partial cross-sectional view illustrating the structure of a semiconductor device according to a seventh embodiment of the present invention. As shown in FIG. 10, the semiconductor device 27 according to the present embodiment has the wiring board composite body 11 of the first embodiment as shown in FIG. 1. In addition, a semiconductor element 24 is mounted, by way of an adhesive agent 125, on the wiring board 14 formed on the wiring board composite body 11, with the semiconductor element 24 and the wiring board 14 being connected by wire-bonding. Although the wiring board composite body of the first embodiment is used as the wiring board composite body 11 in FIG. 10, any wiring board composite body of the second to fifth embodiments can also be used. Furthermore, although a single semiconductor element 24 is mounted on the wiring board 14 in FIG. 10, a plurality of semiconductor devices 24 may be mounted thereon.

The semiconductor element 24 is adhered to the wiring board 14 of the wiring board composite body 11 by the adhesive agent 125, and a surface opposite to the adhesion surface of the semiconductor element 24 is electrically connected to the wiring board 14 by a bonding wire 26. Organic material or silver paste, for example, is used as the adhesive material 25. The bonding wire 26, which is composed of a material including mainly gold, electrically connects both electrodes of the semiconductor element 24 and the wiring board 14.

A stiffener and a heat spreader may be mounted on the semiconductor device 27.

Next, the operation and effect of the present embodiment will be described. In the present embodiment, since the semiconductor device 27 is formed using the supporting substrate 15 composed of the supporting body 12 and the metal body 13, the semiconductor device 27 formed by the supporting substrate 15 will be a stable structure with less warping and swells, if the material of the supporting body 12 is highly rigid. Accordingly, mounting precision increases when forming the semiconductor device 24 by mounting the semiconductor element 24 on the wiring board composite body 11. If, on the other hand, the material of the supporting body 12 is flexible, the semiconductor device 27 can be manufactured at low cost, since roll-to-roll or reel-to-reel production can be employed. Furthermore, production quantity of the semiconductor device 27 can be increased, since a wiring board 14 having a plurality of metal bodies 13 can be formed on a plurality of surfaces of the supporting body 12. In addition, since the wiring board composite body 11 and the semiconductor element 24 are connected by wire-bonding, the semiconductor device 27 can be provided at low cost.

Next, a semiconductor device according to an eighth embodiment of the present invention will be described. FIG. 11 is a partial cross-sectional view illustrating the structure of the semiconductor device according to an eighth embodiment of the present invention.

As shown in FIG. 11, the semiconductor device 27 according to the present embodiment has the wiring board composite body 11 of the first embodiment as shown in FIG. 1. In addition, a semiconductor element 24 is flip-chip connected, by way of a solder ball 23, to the wiring board 14 formed on the wiring board composite body 11, and underfill resin 25 is injected between the semiconductor element 24 and the wiring board 14, and furthermore, mold resin 28 is provided on the wiring board 14 so as to cover the semiconductor element 24. Although the wiring board composite body of the first embodiment is used as the wiring board composite body 11 in FIG. 11, any wiring board composite body of the second to fifth embodiments can also be used. Furthermore, in FIG. 11, although a single semiconductor element 24 is mounted on the wiring board 14, a plurality of semiconductor devices 24 may be mounted thereon. In addition, although the connection between the semiconductor element 24 and the wiring board composite body 11 is a flip-chip connection, wire-bonding connection may also be used, or a combination of these may be used for a plurality of semiconductor elements 14.

The semiconductor element 24 is connected to the wiring board composite body 11 by way of a solder ball 23, and underfill resin 25 is filled in the space between the semiconductor element 24 and the wiring board composite body 11. The underfill resin 25 reduces the difference of coefficients of thermal expansion between the wiring board composite body 11 and the semiconductor element 24 to prevent destruction of the solder ball 23. However, if the solder ball 23 has a strength that assures high reliability, it is not necessary to be filled with the underfill resin 25. The solder ball 23, a ball composed of a solder material, is attached to the wiring board composite body 11 by plating, ball transferring, printing or the like. The solder ball 23 is composed of, for example, eutectic solder of lead/tin alloy or a lead-free solder material. The underfill resin 25 is composed of, for example, an epoxy material with silica filler added thereto. Electroconductive paste or copper bump, for example, may be used for joining the wiring board composite body 11 and the semiconductor element 24. In the present embodiment, solder ball 23 is used.

A stiffener and a heat spreader may be mounted on the semiconductor device 27.

Next, the operation and effect of the present embodiment will be described. In the present embodiment, since the semiconductor device 27 is formed using the supporting substrate 15 composed of the supporting body 12 and the metal body 13, the semiconductor device 27 formed by the supporting substrate 15 will be a stable structure with less warping and swells, if the material of the supporting body 12 is highly rigid, Accordingly, mounting precision increases when forming the semiconductor device 24 by mounting the semiconductor element 24 on the wiring board composite body 11. If, on the other hand, the material of the supporting body 12 is flexible, the semiconductor device 27 can be manufactured at low cost, since roll-to-roll or reel-to-reel production can be employed. Furthermore, production quantity of the semiconductor device 27 can be increased, since a wiring board 14 having a plurality of metal bodies 13 can be formed on a plurality of surfaces of the supporting body 12. In addition, since the semiconductor element 24 is covered with the mold resin 28, the semiconductor element 24 can be protected. Furthermore, rigidity of the semiconductor device 27 can be strengthened by providing the mold resin 28, whereby reliability of the semiconductor device 27 increases.

Note that, although a semiconductor device using a wiring board composite body has been described in the sixth to eighth embodiments, a semiconductor device can be constituted with the supporting body 12 removed. Furthermore, a semiconductor device can be constituted with both the supporting body 12 and the metal body 13 removed.

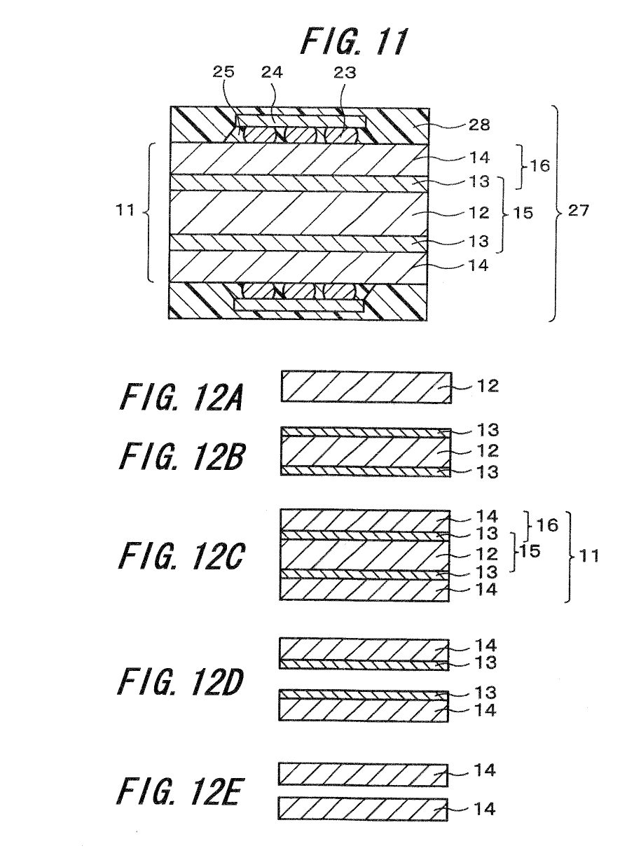

In the following, a method for manufacturing a wiring board composite body and a wiring board will be described. First, a method for manufacturing a wiring board composite body and a wiring board according to a ninth embodiment of the present invention will be described. FIGS. 12A to 12E are partial cross-sectional views illustrating, in the order of processes, the method for manufacturing a wiring board composite body and a wiring board according to the present embodiment. Here, cleaning and heat treatment are performed between the processes, as appropriate.

First, as shown in FIG. 12A, a supporting body 12 is prepared. The supporting body 12 may be composed of organic compounds such as epoxy resin, epoxy acrylate resin, urethane acrylate resin, polyester resin, phenol resin, polyimide resin, BCB (benzocyclobutene), PBO (polybenzoxazole) or polynorbornene resin; inorganic compounds such as ceramic, metal oxide or glass; or metal such as copper, nickel, aluminum, gold, silver, palladium, platinum, iron, stainless steel, zinc, magnesium, titanium, 42 alloy, chromium, vanadium, rhodium, molybdenum or cobalt; and furthermore, a plurality of these materials. As necessary, the supporting body 12 may be treated by processes such as wet cleaning, dry cleaning, planarization, or roughening. In the present embodiment, stainless steel SUS304 is used as the supporting body 12.

As shown in FIG. 12B, the metal bodies 13 are integrated on the planes formed on the top and the bottom of the supporting body 12 to form the supporting substrate 15. The metal body 13 may have the same shape or size, in planar view, as the plane of the supporting body 12, or may have a different shape or size. For example, the metal body 13 may be composed of any one of copper, nickel, aluminum, gold, silver, palladium, platinum, iron, stainless steel, zinc, magnesium, titanium, 42 alloy, chromium, vanadium, rhodium, molybdenum and cobalt, or a plurality of these materials. Particularly, copper is suitable in terms of cost and workability. In the present embodiment, copper is used as the metal body 13.

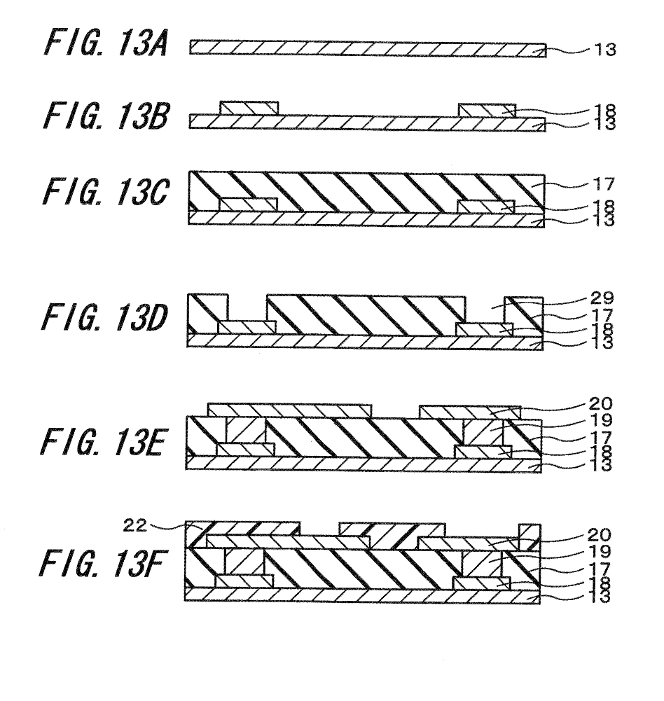

Next, as shown in FIG. 12C, wiring boards 14 are formed on respective metal bodies 13. The method for manufacturing the wiring board 14 will be described referring to FIG. 13. The wiring board composite body 11 is formed by the processes of FIGS. 12A to 12C.

Next, as shown in FIG. 12D, the supporting body 12 and the wiring board 16 provided with the metal body are separated. As the separation method, laser processing, dry etching, wet etching, or blasting is employed. Alternatively, as described in the first embodiment, a method may be employed, which can easily perform the separation by preliminarily rendering the interface between the supporting body 12 and the metal body 13 to be a low-adhesive interface.

Next, as shown in FIG. 12E, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface.

When separating the wiring board 14 and the metal body 13, the metal body 13 may be completely separated, or may be separated so that a portion of the metal body is left on the wiring board 15. If the metal body 13 is completely separated, the wiring board 14 becomes a coreless substrate having only the wiring body, whereby thinning of the wiring board can be realized. If a portion of the metal bodies 13 is left, the remaining metal bodies 13 can function as an external terminal, stiffener, or heat spreader.

Here, a method for manufacturing the wiring board 14 will be described, referring to FIG. 13. The wiring board 14 is formed on the metal body 13 provided in the supporting body 12, as shown in FIG. 128.

First, as shown in FIG. 13A, a metal body 13 arranged on the supporting body 12 is prepared. In FIG. 13A, the supporting body 12 is not shown and only the metal body 13 is illustrated. The metal body 13 may be treated by processes such as wet cleaning, dry cleaning, planarization, or roughening, as necessary.

Next, as shown in FIG. 13B, a lower wiring 18 is formed on the metal body 13 by a subtractive, semi-additive or full-additive method, for example. The subtractive method is a method for obtaining a desired pattern by forming a resist of the desired pattern on a copper foil provided on the substrate and stripping the resist after having etched unnecessary copper foil. The semi-additive method is a method for obtaining a desired wiring pattern by forming a power supplying layer by electroless plating, spattering, CVD (chemical vapor deposition) or the like, and subsequently forming a resist opened in the desired pattern, depositing metal in the resist opening by electroplating and, after having removed the resist, etching the power supplying layer. The full-additive method is a method obtaining a desired wiring pattern by absorbing the electroless plating catalyst on the substrate and subsequently forming a pattern on the resist, activating the catalyst with the resist left as an insulating film, and depositing metal on the opening of the insulating film by electroless plating. The lower wiring 18 is formed by using, for example, at least one type of metals selected from a group consisting of copper, silver, gold, nickel, aluminum and palladium, or an alloy having these as major components. Particularly, it is preferred to be formed by copper in terms of electric resistance and cost. In the present embodiment, copper is used.

Next, as shown in FIG. 13C, an insulating layer 17 is laminated on the metal body 13 including a lower wiring 18. The insulating layer 17 is composed of a photosensitive or a non-photosensitive organic material, for example, wherein the organic material may be epoxy resin, epoxy acrylate resin, urethane acrylate resin, polyester resin, phenol resin, polyimide resin, BCB (benzocyclobutene), PBO (polybenzoxazole) or polynorbornene resin, for example, and further, materials such as woven or unwoven fabric formed from glass cloth or aramid fiber with epoxy resin, epoxy acrylate resin, urethane acrylate resin, polyester resin, phenol resin, polyimide resin, BCB (benzocyclobutene), PBO (polybenzoxazole) or polynorbornene resin impregnated therein may be employed. In the present embodiment, epoxy resin with aramid fiber impregnated therein is used.

Next, as shown in FIG. 13D, a via hole 29 is provided in the insulating layer 17. The via hole 29 is formed by photolithography if a photosensitive material is used in the insulating layer 17. If a non-photosensitive material or a photosensitive material with a low pattern resolution is used in the insulating layer 17, the via hole 29 is formed by laser processing, dry etching, or blasting. In the present embodiment, laser processing is used.

Next, as shown in FIG. 13E, at least one type of metal selected from a group including for example, copper, silver, gold, nickel, aluminum and palladium, or an alloy having these metals as major components is filled in the via hole 29 to form a via 19. The filling is conducted by method of electroplating, electroless plating, printing, molten metal suction, or the like. In addition, according to a method in which the insulating layer 17 is formed after having formed a post for electric conduction at the position of the via 19 beforehand, and the via 19 is formed by grinding surface of the insulating layer 17 by polishing to expose the electric conduction post, it is not necessary to provide an opening on the insulating layer 17. In addition, the via 19 may be formed by the same process as that for the upper wiring 20. Furthermore, the upper wiring 20 is formed on the via 19 by a subtractive, semi-additive or full-additive method, for example. For the upper wiring 20, at least one type of metal selected from a group including for example, copper, silver, gold, nickel, aluminum and palladium, or an alloy having these metals as major components is used. Particularly, it is preferred, in terms of electrical resistance and cost, to be composed of copper. In the present embodiment, the lower wiring 18, the upper wiring 20 and the via 19 are composed of copper using a semi-additive method.

Next, as shown in FIG. 13F, a pattern of the solder resist 22 is formed on insulating layer 17 including a portion of the upper wiring 20. The solder resist 22 is formed in order to protect the surface circuit of the wiring board and exhibit flame resistance. The material includes organic materials such as epoxy, acrylic, urethane or polyimide, and may have inorganic or organic filler added thereto, as necessary. In addition, an arrangement in which the solder resist 22 is not provided on the wiring board may also be used. Additionally, although an example of manufacturing from the wiring is shown in FIG. 13, a method of manufacturing from the insulating layer may be employed.

Additionally, although an arrangement comprising a single insulating layer 17, and the lower wiring 18 and the upper wiring 20 insulated by the insulating layer 17 is shown in FIG. 13, such an arrangement is not limiting and thus a multi-layer wiring structure may be employed, with a plurality of layers of such a structure laminated thereon.

According to the method for manufacturing of the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12.

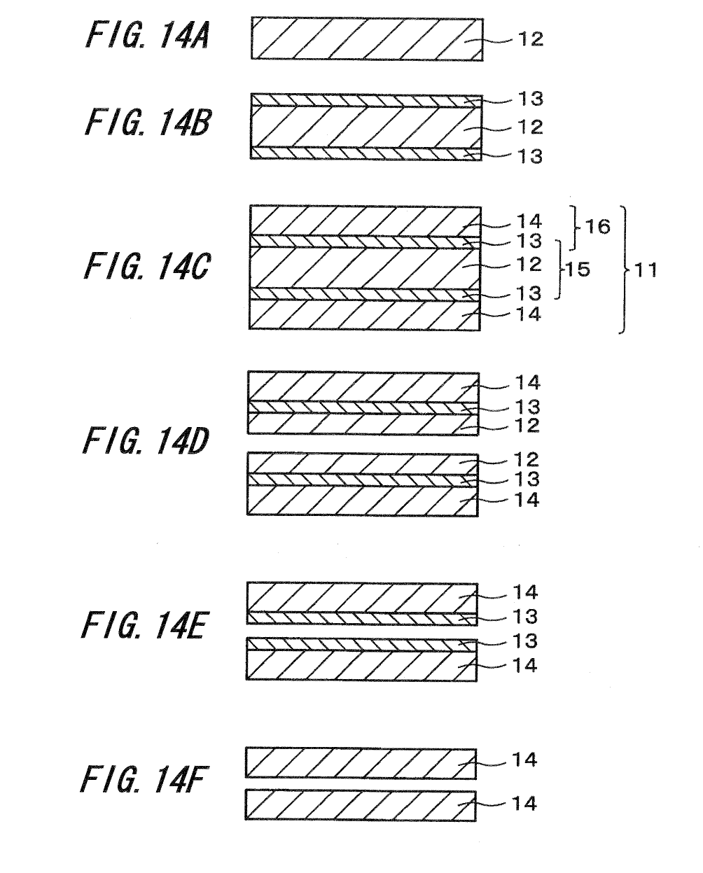

A method for manufacturing a wiring board composite body and a wiring board according to a first variation of the ninth embodiment will be described. FIGS. 14A to 14F are partial cross-sectional views illustrating, in the order of processes, the method for manufacturing a wiring board composite body and a wiring board according to the present embodiment. Here, cleaning and heat treatment are performed between the processes, as appropriate.

First, as shown in FIG. 14A, a supporting body 12 is prepared. The supporting body 12 is composed of a material similar to the ninth embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

Next, as shown in FIG. 14B, the metal bodies 13 are integrated on the plane of the supporting body 12 to form the supporting substrate 15. The metal body 13 may have the same shape or size, in planar view, as the plane formed on the supporting body 12, or may have a different shape or size. The metal body 13 is composed of a material similar to the ninth embodiment. Particularly, copper is suitable in terms of cost and workability. In the present embodiment, copper is used as the metal body 13.

Next, as shown in FIG. 14C, the wiring board 14 is formed on the metal body 13. The method for manufacturing the wiring board 14 is similar to that shown in FIG. 13. The wiring board composite body 11 is formed by the processes of FIGS. 14A to 14C.

Next, as shown in FIG. 14D, the supporting body 12 of the wiring board composite body 11 is separated into two parts along a plane parallel to the substrate surface. As the separation method, laser processing, dry etching, wet etching, or blasting is employed. Alternatively, as described in the first embodiment, a method may be employed, which can easily perform the separation by forming the supporting body 12 as a two-layer structure and rendering the boundary surface to be a low-adhesive interface.

Next, as shown in FIG. 14E, the wiring board 16 provided with the metal body and the supporting body 12 are separated. As the separation method, laser processing, dry etching, wet etching, or blasting is employed. Alternatively, as described in the first embodiment, a method may be employed, which can easily perform the separation by preliminarily rendering the boundary between the supporting body 12 and the metal body 13 to be a low-adhesive interface.

Next, as shown in FIG. 14F, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the boundary between the wiring board 14 and the metal body to be a low-adhesive interface. When separating the wiring board 14 and the metal body 13, the metal body 13 may be completely separated, or may be separated so that a portion of the metal body is left on the wiring board 15. If the metal body 13 is completely separated, the wiring board 14 becomes a coreless substrate having only the wiring body, whereby thinning of the wiring board can be realized. If a portion of the metal bodies 13 is left, the remaining metal bodies 13 can function as an external terminal, stiffener, or heat spreader.

According to the method for manufacturing of the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12.

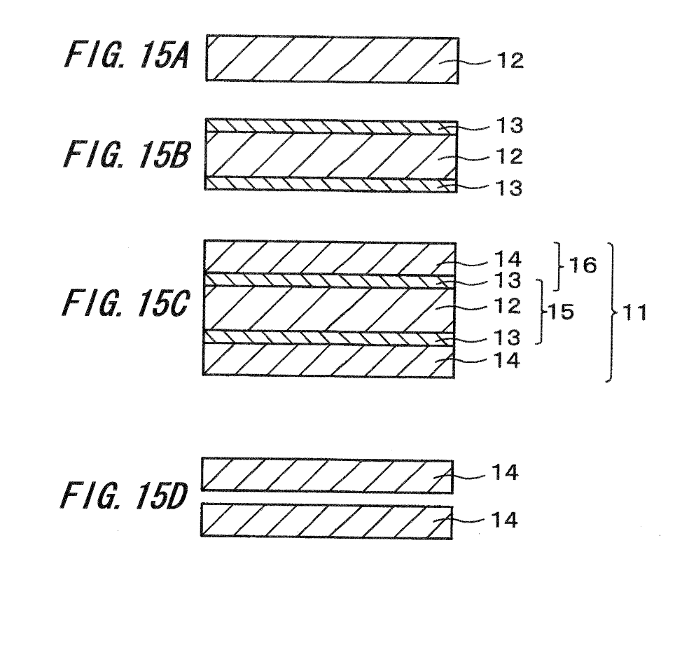

A method for manufacturing a wiring board composite body and a wiring board according to a second variation of the ninth embodiment will be described. FIGS. 15A to 15D are partial cross-sectional views illustrating, in the order of processes, the method for manufacturing a wiring board composite body and a wiring board according to the present embodiment. Here, cleaning and heat treatment are performed between the processes, as appropriate.

First, as shown in FIG. 15A, a supporting body 12 is prepared. The supporting body 12 is composed of a material similar to the ninth embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12.

Next, as shown in FIG. 15B, the metal bodies 13 are integrated on the plane of the supporting body 12 to form the supporting substrate 15. The metal body 13 may have the same shape or size, in planar view, as the plane formed on the supporting body 12, or may have a different shape or size. The metal body 13 is composed of a material similar to the ninth embodiment. Particularly, copper is suitable in terms of cost and workability. In the present embodiment, copper is used as the metal body 13.

Next, as shown in FIG. 15C, the wiring board 14 is formed on the metal body 13. The method for manufacturing the wiring board 14 is similar to that shown in FIG. 13. The wiring board composite body 11 is formed by the processes of FIGS. 15A to 15C.

Next, as shown in FIG. 15D, the supporting substrate 15 and the wiring board 14 are separated. As the separation method, laser processing, dry etching, wet etching, or blasting is employed. Alternatively, as described in the first embodiment, a method may be employed, which can easily perform the separation by rendering the interface between the metal body 13 and the wiring board 14 to be a low-adhesive interface.

According to the method for manufacturing of the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12.

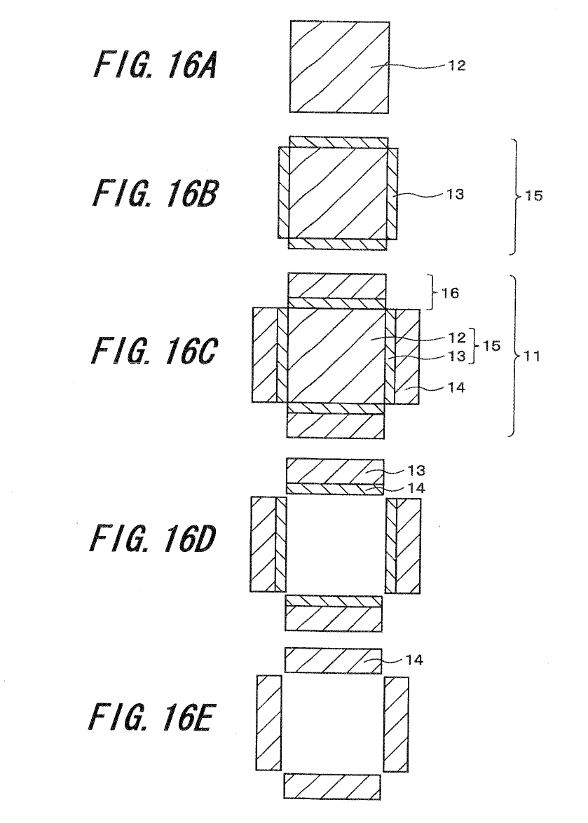

A method for manufacturing a wiring board composite body and a wiring board according to a tenth embodiment of the present invention will be described. FIGS. 16A to 16E are partial cross-sectional views illustrating, in the order of processes, the method for manufacturing a wiring board composite body and a wiring board according to the present embodiment. Here, cleaning and heat treatment are performed between the processes, as appropriate.

First, as shown in FIG. 16A, a supporting body 12 is prepared. The supporting body 12 is composed of a material similar to the ninth embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12. Although a quadrangular prism is used as the supporting body 12 in FIG. 16A, a polygonal column, a polyhedron, or a cylindrical column having a plurality of surfaces may be employed other than a quadrangular prism.

Next, as shown in FIG. 16B, the metal bodies 13 are integrated on the plane of the supporting body 12 to form the supporting substrate 15. The metal body 13 is composed of a material similar to the ninth embodiment. Particularly, copper is suitable in terms of cost and workability. In the present embodiment, copper is used as the metal body 13.

Next, as shown in FIG. 16C, the wiring board 14 is formed on the metal body 13. The method for manufacturing the wiring board 14 is similar to that shown in FIG. 13. The wiring board composite body 11 is formed by the processes of FIGS. 16A to 16C.

Next, as shown in FIG. 16D, the supporting body 12 and the wiring board 16 provided with the metal body are separated. As the separation method, laser processing, dry etching, wet etching, or blasting is employed. Alternatively, as described in the first embodiment, a method may be employed, which can easily perform the separation by preliminarily rendering the interface between the supporting body 12 and the metal body 13 to be a low-adhesive interface.

Next, as shown in FIG. 16E, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface.

When separating the wiring board 14 and the metal body 13, the metal body 13 may be completely separated, or may be separated so that a portion of the metal body is left on the wiring board 14. In addition, the process of separating the wiring board 14 from the wiring board composite body 11 may be a process of separating the supporting body 12 of the wiring board composite body 11 into a plurality of pieces to form a plurality of wiring boards 16 provided with the metal body each formed on the supporting bodies 12, and further separating the supporting body 12 of the wiring board 16 provided with the metal body, and subsequently separating the metal body 13 from the wiring board 16 provided with the metal body. Alternatively, the supporting substrate composed of the supporting body 12 and the metal body 13 may be separated from the wiring board composite body 11 all together. In either case, laser processing, dry etching, wet etching, or blasting may be used as the separation method. Alternatively, as described in the first embodiment, a method may be employed, which can easily perform the separation by preliminarily rendering the interface between the wiring board 14 and the metal body 13 to be a low-adhesive interface.

The wiring board 14 is formed from the wiring board composite body 11 by the processes of FIGS. 16C to 16E. According to the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be substantially increased, since a wiring board 14 having a plurality of metal bodies 13 can be formed on a plurality of surfaces of the supporting body 12.

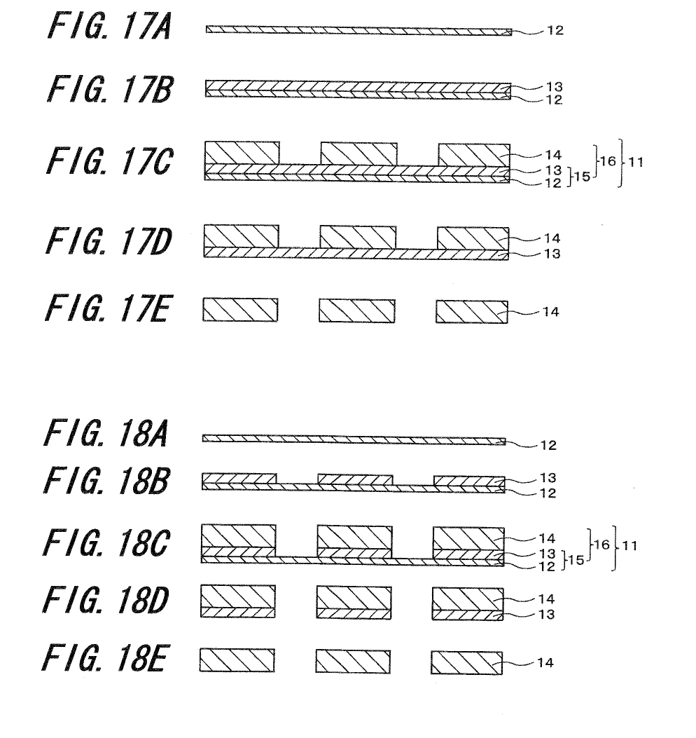

A method for manufacturing a wiring board composite body and a wiring board according to an eleventh embodiment of the present invention will be described. FIGS. 17A to 17E are partial cross-sectional views illustrating, in the order of processes, the method for manufacturing a wiring board composite body and a wiring board according to the present embodiment. Although an example in which the metal body 13 and the wiring board 14 are formed on one side of the supporting body 12 as shown in FIG. 17, they may be formed on both sides of the supporting body 12.

First, as shown in FIG. 17A, a supporting body 12 is prepared. The supporting body 12 is composed of a material similar to the ninth embodiment. In addition, the supporting body 12 may be composed of highly rigid material which can be used repeatedly, or may be composed of highly flexible material which can be freely deformed so that it can be suitably selected according to the purpose. In the present embodiment, stainless steel SUS304 is used as the supporting body 12. As necessary, the supporting body 12 may be treated by processes such as wet cleaning, dry cleaning, planarization, or roughening. In the present embodiment, stainless steel SUS304 is used as the supporting body 12.

Next, as shown in FIG. 17B, planar metal bodies 13 are integrated on the plane of the supporting body 12 to form the supporting substrate 15. The metal body 13 is composed of a material similar to the ninth embodiment. Particularly, copper is suitable in terms of cost and workability. In the present embodiment, copper is used as the metal body 13.

Next, as shown in FIG. 17C, a plurality of wiring boards 14 are formed on the same plane of the metal body 13. The method for manufacturing the wiring board 14 is similar to that shown in FIG. 13. In FIG. 17C, although a space is provided between each of the wiring boards 14, the space may be formed using laser processing, dry etching, wet etching, or blasting after the wiring board has been formed on the metal body 13, and the wiring board 14 may be formed individually, with the space already existing. The wiring board composite body 11 is formed by the processes of FIGS. 17A to 17C.

Next, as shown in FIG. 17D, the supporting body 12 and the wiring board 16 provided with the metal body are separated. As the separation method, laser processing, dry etching, wet etching, or blasting is employed. Alternatively, as described in the first embodiment, a method may be employed, which can easily perform the separation by preliminarily rendering the interface between the supporting body 12 and the metal body 13 to be a low-adhesive interface.

Next, as shown in FIG. 17E, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface. When separating the wiring board 14 and the metal body 13, the metal body 13 may be completely separated, or may be separated so that a portion of the metal body is left on the wiring board 15. Additionally, in the process of separating the wiring board 14 from the wiring board composite body 11, the supporting substrate 15 composed of the supporting body 12 and the metal body 13 may be separated from the wiring board composite body 11 all together. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface.

The wiring board 14 is formed from the wiring board composite body 11 by the processes of FIGS. 17C to 17E.

According to the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12.

A method for manufacturing a wiring board composite body and a wiring board according to a twelfth embodiment of the present invention will be described. FIGS. 18A to 18E are partial cross-sectional views illustrating, in the order of processes, the method for manufacturing a wiring board composite body and a wiring board according to the present embodiment.

First, as shown in FIG. 18A, a supporting body 12 is prepared. The supporting body 12 is composed of a material similar to the ninth embodiment. The supporting body 12 may be treated by processes such as wet cleaning, dry cleaning, planarization, or roughening, as necessary. In the present embodiment, stainless steel SUS304 is used as the supporting body 12.

Next, as shown in FIG. 18B, a plurality of metal bodies 13 are arranged mutually spaced apart on the plane of the supporting body 12, and the supporting body 12 and the metal bodies 13 are integrated to form the supporting substrate 15. The metal bodies 13 are composed of a material similar to the ninth embodiment. Particularly, copper is suitable in terms of cost and workability. In the present embodiment, copper is used as the metal body 13. In FIG. 18B, although a plurality of metal bodies 13 are formed on one side of the supporting body 12, they may be formed on both sides of the supporting body 12. In addition, it may be arranged, as with the an exemplary variation of the fourth embodiment, such that a plurality of supporting bodies 12 function as joints of a plurality of wiring boards 16 provided with the metal body.

Next, as shown in FIG. 18C, the wiring board 14 is formed on each of the metal bodies 13. The method for manufacturing the wiring board 14 is similar to that shown in FIG. 13. The wiring board composite body 11 is formed by the processes of FIGS. 18A to 18C.

Next, as shown in FIG. 18D, the supporting body 12 and the wiring board 16 provided with the metal body are separated. As the separation method, laser processing, dry etching, wet etching, or blasting is employed. Alternatively, as described in the first embodiment, a method may be employed, which can easily perform the separation by preliminarily rendering the interface between the supporting body 12 and the metal body 13 to be a low-adhesive interface.

Next, as shown in FIG. 18E, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface. When separating the metal body 13 from the wiring board 16 provided with the metal body, the metal body 13 may be completely separated, or may be separated so that a portion of the metal body is left on the wiring board 15.

Additionally, in the process of separating the wiring board 14 from the wiring board composite body 11, the supporting substrate 15 composed of the supporting body 12 and the metal body 13 may be separated from the wiring board composite body 11 all together. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface.

The wiring board 14 is formed from the wiring board composite body 11 by the processes of FIGS. 18C to 18E.

According to the present embodiment, the wiring board composite body 11 and the wiring board 14 can be formed efficiently. En other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12.

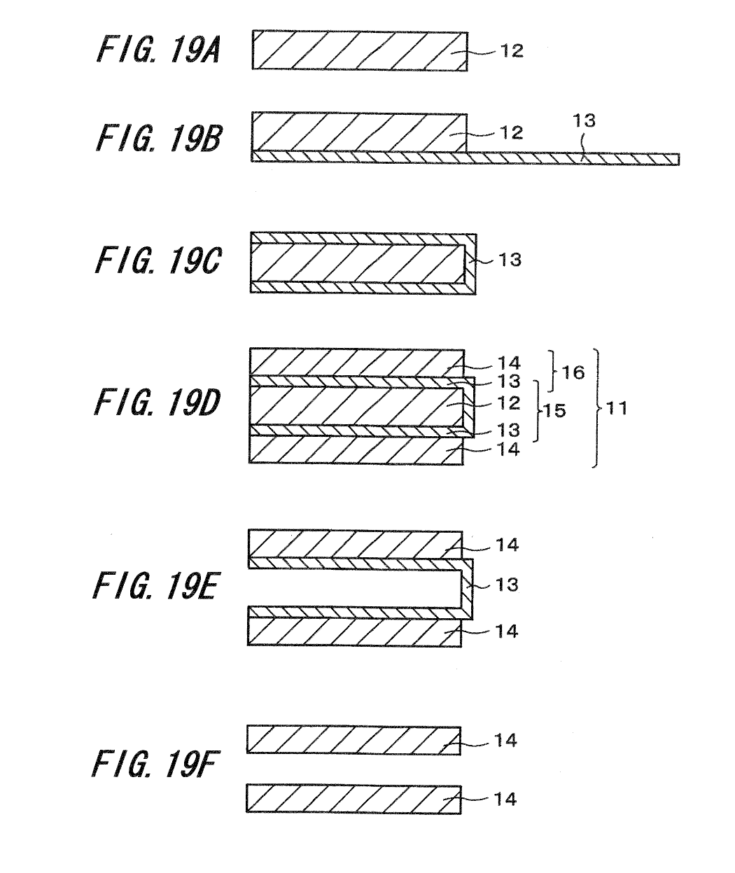

A method for manufacturing a wiring board composite body and a wiring board according to a thirteenth embodiment of the present invention will be described. FIGS. 19A to 19F are partial cross-sectional views illustrating, in the order of processes, the method for manufacturing a wiring board composite body and a wiring board according to the present embodiment.

First, as shown in FIG. 19A, a supporting body 12 is prepared. The supporting body 12 is composed of a material similar to the ninth embodiment. The supporting body 12 may be treated by processes such as wet cleaning, dry cleaning, planarization, or roughening, as necessary. In the present embodiment, stainless steel SUS304 is used as the supporting body 12.

Next, as shown in FIGS. 19B and 19C, a supporting body 12 is arranged on a planar metal body 13, the metal body 13 is bent into a C-shape so that the metal body 13 overlaps with the top and the bottom surfaces of the supporting body 12, and the supporting body 12 and the bent metal body 13 are integrated to form the supporting substrate 15. In FIG. 19C, although the bent metal body 13 is arranged along the circumference of the supporting body 12, there may be a space provided in a portion of the boundary between the supporting body 12 and the metal body 13. In addition, the supporting body 12 may function as a joint which contacts with only a portion of the bent metal body 13, as in the exemplary variation of the fifth embodiment, and there may be one or more supporting bodies 12. The metal body 13 is composed of a material similar to the ninth embodiment. Particularly, copper is suitable in terms of cost and workability. In the present embodiment, copper is used as the metal body 13.

Next, as shown in FIG. 19D, wiring boards 14 are formed on each of the top and the bottom surfaces formed on the metal body 13. The method for manufacturing the wiring board 14 is similar to that shown in FIG. 13. The wiring board composite body 11 is formed by the processes of FIGS. 19A to 19D.

Next, as shown in FIG. 19E, the wiring board 16 provided with the metal body and the supporting body 12 are separated. As the separation method, laser processing, dry etching, wet etching, or blasting is employed. Alternatively, as described in the first embodiment, a method may be employed, which can easily perform the separation by preliminarily rendering the interface between the supporting body 12 and the metal body 13 to be a low-adhesive interface.

Next, as shown in FIG. 19F, the wiring board 14 and the metal body 13 are separated. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface. When separating the metal body 13 from the wiring board 14, separation may be performed such that the metal body 13 is completely separated or such that a part of the metal body 13 remains on the wiring board 15. In the process of separating the wiring board 14 from the wiring board composite body 11, the supporting substrate 15, constituted of the supporting body 12 and the metal body 13, may be separated in its entirety from the wiring board composite body 11. As the separation method, laser processing, dry etching, wet etching, or blasting is employed. Alternatively, as described in the first embodiment, a method may be employed, which can easily perform the separation by preliminarily rendering the interface between the wiring board 14 and the metal body 13 to be a low-adhesive interface. When separating the metal body 13 from the wiring board 16 provided with the metal body, separation may be performed after the bent metal body 13 is returned to its original condition before it was bent.

The wiring board 14 is formed from the wiring board composite body 11 by the processes of FIGS. 19D to 19F.

According to the present embodiment, the wiring board composite body 11 and the wiring board 14 can be formed efficiently. In other words, since the wiring board composite body 11 is formed using the supporting substrate 15 composed of the supporting body 12 and the metal body 13, the wiring board composite body 11 formed of the supporting substrate 15 will be a stable structure with less warping and swells, if the material of the supporting body 12 is highly rigid. If, on the other hand, the material of the supporting body 12 is flexible, the wiring board composite body 11 can be formed at low cost, since roll-to-roll or reel-to-reel production can be employed. Furthermore, production quantity of the wiring board 14 can be increased, since a wiring board 14 having a plurality of metal bodies 13 can be formed on a plurality of surfaces of the supporting body 12. Moreover, supporting bodies 12 and supporting substrates 15 having a variety of shapes can be formed by bending the metal body 13. In addition, processing cost of the metal body 13 can be reduced since a single metal body 13 can be handled such that it has a plurality of surfaces.

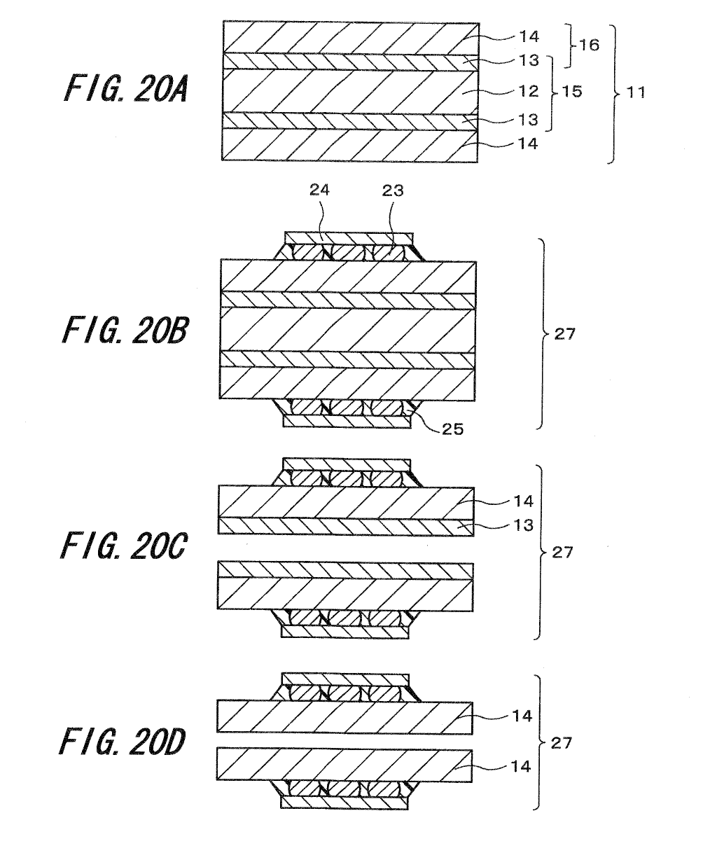

A method for manufacturing a semiconductor device according to a fourteenth embodiment of the present invention will be described. FIGS. 20A to 20D are partial cross-sectional views illustrating, in the order of processes, the method for manufacturing a semiconductor device according to the present embodiment. In the present embodiment, description will be provided from a state in which the wiring board 14 has been formed on the supporting substrate 15, as shown in FIG. 20A. Although the wiring board composite body of the first embodiment is used as the wiring board composite body 11 in FIG. 20A, a wiring board composite body of other embodiments and their exemplary variations can be similarly used.

As shown in FIG. 20B, the semiconductor element 24 and the wiring board 14 are flip-chip connected to the wiring board 14 formed on the wiring board composite body 11 by way of a solder ball 23. Subsequently, underfill resin 25 is filled between the wiring board 14 on which the solder ball 23 is formed and the semiconductor element 24. The underfill resin 25 is used for the purpose of reducing the difference of coefficients of thermal expansion between the wiring board composite body 11 and the semiconductor element 24 to prevent destruction of the solder ball 23. However, if the solder ball 23 has a strength that assures high reliability, it is not necessary to be filled with the underfill resin 25. The solder ball 23, which is a minute ball composed of a solder material, is formed by plating, ball transferring, printing or the like. The material of the solder ball 23 may be suitably selected from, for example, eutectic solder of lead/tin alloy or a lead-free solder. The underfill resin 25, which is composed of, for example, an epoxy material, is filled after the semiconductor element 24 has been connected by the solder ball 23. Electroconductive paste or copper bump, for example, may be used for joining the wiring board composite body 11 and the semiconductor element 24. Additionally, although a flip-chip connection is shown as an exemplary connection of the semiconductor element 24 in FIG. 20B, wire-bonding connection may also be employed. With the above-mentioned processes, the semiconductor devices according to the present embodiment can be manufactured.

In addition, as shown in FIGS. 20C and 20D, the supporting body 12 and/or the metal body 13 can be separated from the semiconductor device 27.

In FIG. 20C, the supporting body 12 is removed from the semiconductor device 27, and the semiconductor device having the semiconductor element 24 mounted on the wiring board 16 provided with the metal body is separated. As the separation method, laser processing, dry etching, wet etching, or blasting is employed. Alternatively, as described in the first embodiment, a method may be employed, which can easily perform the separation by preliminarily rendering the separation surface to be a low-adhesive interface.

In FIG. 20D, the supporting substrate 15 is removed from the semiconductor device 27 to separate the semiconductor device having the semiconductor element 24 mounted on the wiring board 14. As the separation method, laser processing, dry etching, wet etching, or blasting is employed. Alternatively, as described in the first embodiment, a method may be employed, which can easily perform the separation by preliminarily rendering the separation surface to be a low-adhesive interface. When separating the metal body 13 from the wiring board 16 provided with the metal body, the metal body 13 may be completely separated, or may be separated so that a portion of the metal body is left on the wiring board 15. In addition, the process of separating the wiring board 14 from the wiring board composite body 11 may be a process of separating the supporting body 12 of the wiring board composite body 11 into two parts along a plane parallel to the surface of the wiring board 14 and subsequently separating the supporting body 12 of the wiring board 16 provided with the metal body formed on the supporting body 12, and separating the metal body 13 from the wiring board 16 provided with the metal body. Alternatively, the supporting substrate 15 composed of the supporting body 12 and the metal body 13 may be separated from the wiring board composite body 11 all together. In either case, laser processing, dry etching, wet etching, or blasting may be used as the separation method. Alternatively, a method may be employed, which can easily perform the separation by preliminarily rendering the separation surface to be a low-adhesive interface.

According to the present embodiment, the semiconductor device 27 can be formed efficiently. In other words, since the semiconductor device 27 is formed using the supporting substrate 15 composed of the supporting body 12 and the metal body 13, the semiconductor device 27 formed from the supporting substrate 15 will be a stable structure with less warping and swells, if the material of the supporting body 12 is highly rigid. Accordingly, mounting precision increases when forming the semiconductor device 27 by mounting the semiconductor element 24 on the wiring board composite body 11. If, on the other hand, the material of the supporting body 12 is flexible, the semiconductor device 27 can be formed at low cost, since roll-to-roll or reel-to-reel production can be employed. Furthermore, production quantity of the semiconductor device 27 can be increased, since a wiring board 14 having a plurality of metal bodies 13 can be formed on a plurality of surfaces of the supporting body 12.

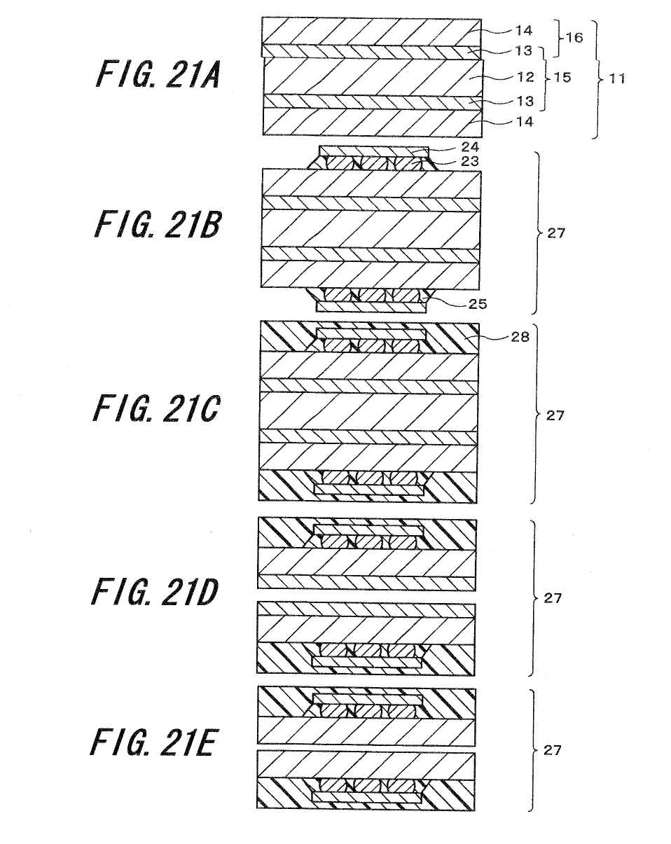

A method for manufacturing a semiconductor device according to a fifteenth embodiment of the present invention will be described. FIGS. 21A to 21E are partial cross-sectional views illustrating, in the order of processes, the method for manufacturing a semiconductor device according to the present embodiment. Description will be provided from a state in which the wiring board 14 has been formed on the supporting substrate 15, as shown in FIG. 21A. Although the wiring board composite body of the first embodiment is used as the wiring board composite body 11 in FIG. 21A, a wiring board composite body of other embodiments and their exemplary variations can be similarly used.

As shown in FIG. 21B, the semiconductor element 24 and the wiring board 14 are flip-chip connected to the wiring board 14 formed on the wiring board composite body 11 by way of a solder ball 23. Subsequently, underfill resin 25 is filled between the wiring board 14 on which the solder ball 23 is formed and the semiconductor element 24. The underfill resin 25 is used for the purpose of reducing the difference of coefficients of thermal expansion between the wiring board composite body 11 and the semiconductor element 24 to prevent destruction of the solder ball 23. However, if the solder ball 23 has a strength that assures high reliability, it is not necessary to be filled with the underfill resin 25. The solder ball 23, which is a minute ball composed of a solder material, is formed by plating, ball transferring, printing or the like. The material of the solder ball 23 may be suitably selected from, for example, eutectic solder of lead/tin alloy or a lead-free solder. The underfill resin 25, which is composed of, for example, an epoxy material, is filled after the semiconductor element 24 has been connected by the solder ball 23. Electroconductive paste or copper bump, for example, may be used for joining the wiring board composite body 11 and the semiconductor element 24. Additionally, although a flip-chip connection is shown as an exemplary connection of the semiconductor element 24 in FIG. 21B, wire-bonding connection may also be employed.

Next, as shown in FIG. 21C, mold resin 28 is formed so as to cover the semiconductor element 24. The mold resin 28, which is composed of, for example an epoxy material mixed with silica filler, is provided by transfer molding, compression molding, a printing or the like using a mold so as to cover the mounted semiconductor element 24 and the wiring of the connecting portions. With the above-mentioned processes, the semiconductor devices according to the present embodiment can be manufactured.

In addition, as shown in FIGS. 21D and 21E, the supporting body 12 and/or the metal body 13 can be separated from the semiconductor device 27.

In FIG. 21D, the supporting body 12 is removed from the semiconductor device 27 to separate the semiconductor device having the semiconductor element 24 mounted on the wiring board 16 provided with the metal body. As the separation method, laser processing, dry etching, wet etching, or blasting is employed. Alternatively, as described in the first embodiment, a method may be employed, which can easily perform the separation by preliminarily rendering the separation surface to be a low-adhesive interface.

In FIG. 21E, the supporting substrate 15 is removed from the semiconductor device 27 to separate the semiconductor device having the semiconductor element 24 mounted on the wiring board 14. As the separation method, laser processing, dry etching, wet etching, or blasting is employed. Alternatively, as described in the first embodiment, a method may be employed, which can easily perform the separation by preliminarily rendering the separation surface to be a low-adhesive interface. When separating the metal body 13 from the wiring board 16 provided with the metal body, the metal body 13 may be completely separated, or may be separated so that a portion of the metal body is left on the wiring board 15. In addition, the process of separating the wiring board 14 from the wiring board composite body 11 may be a process of separating the supporting body 12 of the wiring board composite body 11 into two parts along a plane parallel to the surface of the wiring board 14 and subsequently separating the supporting body 12 of the wiring board 16 provided with the metal body formed on the supporting body 12, and separating the metal body 13 from the wiring board 16 provided with the metal body. Alternatively, the supporting substrate 15 composed of the supporting body 12 and the metal body 13 may be separated from the wiring board composite body 11 all together. In either case, laser processing, dry etching, wet etching, or blasting may be used as the separation method. Alternatively, as described in the first embodiment, a method may be employed, which can easily perform the separation by preliminarily rendering the separation surface to be a low-adhesive interface.

According to the present embodiment, the semiconductor device 27 can be formed efficiently. In other words, since the semiconductor device 27 is formed using the supporting substrate 15 composed of the supporting body 12 and the metal body 13, the semiconductor device 27 formed from the supporting substrate 15 will be a stable structure with less warping and swells, if the material of the supporting body 12 is highly rigid. Accordingly, mounting precision increases when forming the semiconductor device 24 by mounting the semiconductor element 24 on the wiring board composite body 11. If, on the other hand, the material of the supporting body 12 is flexible, the semiconductor device 27 can be formed at low cost, since roll-to-roll or reel-to-reel production can be employed. Furthermore, production quantity of the semiconductor device 27 can be increased, since a wiring board 14 having a plurality of metal bodies 13 can be formed on a plurality of surfaces of the supporting body 12. In addition, reliability of the semiconductor device 27 increases since the semiconductor device 24 is sealed with the mold resin.

This application claims priority based on Unexamined Japanese Patent Application No. 2006-238997, filed on Sep. 4, 2006, the disclosure of which is incorporated in its entirety.

### INDUSTRIAL APPLICABILITY

The present invention is advantageous for applying to a wiring board composite body provided by fabricating multilayer wiring on a supporting substrate composed of a supporting body and metal bodies, for example, SiP (System in Package) or the like, which constructs a system using a single package by combining a plurality of existing chips.

1. A wiring board composite body comprising:
a supporting body;
a metal body arranged on the supporting body;
and a plurality of wiring boards formed on the metal body supported by the supporting body,
wherein the wiring boards comprise an insulation layer, upper and lower wirings insulated by the insulation layer, and a via for connecting the upper and the lower wirings.

2. The wiring board composite body according to claim 1, wherein the metal body is arranged on each of a plurality of surfaces of the single supporting body, and the wiring board is formed on the metal body.

3. The wiring board composite body according to claim 1, wherein the metal body is plurally provided on the single supporting body, and the wiring boards are formed on the metal bodies.

4. The wiring board composite body according to claim 1, wherein the metal body is arranged on the plurality of supporting bodies in a manner lying between the adjacent supporting bodies, whereby the supporting bodies and the metal body is integrated and the wiring board is formed on the metal body.

5. The wiring board composite body according to claim 1, wherein the metal body is formed in a bent manner to extend from the front to the back of the single supporting body around its side, whereby the metal body is supported by the supporting body.

6. The wiring board composite body according to claim 1, wherein the cross section of the metal body is C-shaped, and the supporting body is sandwiched at an open end of the metal body, whereby the metal body is supported by the supporting body.

7. The wiring board composite body according to claim 1, wherein a low-adhesive interface, which facilitates separation of the adhesion surface, is formed either between the supporting body and the metal body or between the metal body and the wiring board, or both.

8. The wiring board composite body according to claim 7, wherein the low-adhesive interface is provided by forming, between the supporting body and the metal body, a layer composed of a material which is different from the material of the supporting body and the metal body, whereas the low-adhesive interface is provided by forming, between the metal body and the wiring board, a layer composed of a material which is different from the material of the metal body and the wiring board.

9. The wiring board composite body according to claim 1, wherein the supporting body and/or the metal body has a first and a second layers, each composed of their respective component materials, and a low-adhesive interface is formed between the first layer and the second layer by forming, between the first and the second layer, a third layer composed of a material which is different from the component material.

10. A semiconductor device wherein a semiconductor element is connected to the wiring board composite body according to claim 1.

11. The semiconductor device according to claim 10, wherein the semiconductor element is connected to the wiring board composite body by flip-chip connection or wire-bonding connection.

12. A method for manufacturing a wiring board composite body comprising the steps of:
forming a supporting substrate composed of a supporting body and a metal body; and
forming a plurality of wiring boards on one or more planes on the metal body in the supporting substrate comprising an insulating layer, upper and lower wirings insulated by the insulating layer, and a via for connecting the upper and the lower wirings.

13. The method for manufacturing the wiring board composite body according to claim 12 comprising the step of
integrating the supporting body and the metal body by providing the one or more metal bodies on one or more planes of the supporting body in the process of forming the supporting substrate composed of the supporting body and the metal body.

14. The method for manufacturing the wiring board composite body according to claim 12 comprising the step of
providing the plurality of metal bodies on the same plane of the supporting body in the process of forming the supporting substrate composed of the supporting body and the metal bodies.

15. The method for manufacturing the wiring board composite body according to claim 12 comprising the step of
bending the metal body to form a plurality of planes on the metal body in the process of forming the supporting substrate composed of the supporting body and the metal body.

16. A method for manufacturing a wiring board comprising the steps of:
forming a supporting substrate composed of a supporting body and a metal body;
forming a plurality of wiring boards on one or more planes on the metal body in the supporting substrate comprising an insulating layer, upper and lower wirings insulated by the insulating layer, and a via for connecting the upper and the lower wirings; and
separating the wiring board from a wiring board composite body formed of the supporting substrate and the wiring board.

17. A method for manufacturing a wiring board comprising the steps of:
forming a supporting substrate composed of a supporting body and a metal body;
forming a plurality of wiring boards on one or more planes on the metal body in the supporting substrate comprising an insulating layer, upper and lower wirings insulated by the insulating layer, and a via for connecting the upper and the lower wirings; and
separating the wiring board having the metal body integrated therewith from a wiring board composite body formed of the supporting substrate and the wiring board.

18. The method for manufacturing a wiring board according to claim 17 comprising the step of
separating the wiring board and the metal body, subsequent to the process of separating the wiring board having the metal body integrated therewith.

19. The method for manufacturing a wiring board according to claim 18 comprising the step of
completely separating the metal body from the wiring board in the process of separating the wiring board and the metal body.

20. The method for manufacturing a wiring board according to claim 18 comprising the step of
leaving a portion of the metal body on the wiring board in the process of separating the wiring hoard and the metal body.

21. A method for manufacturing a semiconductor device comprising the step of
mounting a semiconductor element on a wiring board composite body manufactured by the method for manufacturing the wiring board composite body according to claim 12.

22. The method for manufacturing a semiconductor device according to claim 21 comprising the step of
separating the supporting body from the wiring board composite body after the semiconductor element having been mounted on the wiring board composite body.

23. The method for manufacturing the semiconductor device according to claim 21 comprising the step of
separating the supporting body and the metal body from the wiring board composite body after the semiconductor element having been mounted on the wiring board composite body.

24. A method for manufacturing a semiconductor device comprising the step of
mounting a semiconductor element on a wiring board manufactured by the method for manufacturing the wiring board according to claim 16.

25. The method for manufacturing the semiconductor device according to claim 21, wherein the semiconductor device and the wiring board are connected by flip-chip connection or wire-bonding connection.

26. The method for manufacturing the semiconductor device according to claim 24, wherein the semiconductor device and the wiring board are connected by flip-chip connection or wire-bonding connection.
